(19) United States
(12) Patent Application Publication
(10) Pub. No.: US 2026/0212174 A1
(43) Pub. Date: Jul. 23, 2026

(54) SYSTEM AND METHOD FOR PROBABILITY-BASED COMPLETION AND OPTIMIZATION OF PARTIAL SYSTEMS

(71) Applicant: The Trustees of Princeton University, Princeton, NJ (US)

(72) Inventors: Prerit TERWAY, Princeton, NJ (US); Niraj K. JHA, Princeton, NJ (US)

(73) Assignee: The Trustees of Princeton University, Princeton, NJ (US)

(21) Appl. No.: 19/134,979

(22) PCT Filed: Nov. 30, 2023
(86) PCT No.: PCT/US2023/081839

§ 371 Date: Jun. 2, 2025

Related U.S. Application Data
(60) Provisional application No. 63/429,619, filed on Dec. 2, 2022.
(60) Provisional application No. 63/435,845, filed on Dec. 29, 2022.
(60) Provisional application No. 63/460,153, filed on Apr. 18, 2023.

(51) Int. Cl. G06N 3/08; G06F 30/27; G06N 3/045; G06N 3/047

(52) U.S. Cl. CPC G06N 3/08; G06F 30/27; G06N 3/045; G06N 3/047

(57) ABSTRACT

Disclosed herein are techniques for completing and/or optimizing partial systems. The disclosed techniques may also check the integrity of the system. The disclosed techniques may also identify and correct error(s) after detecting an anomalous behavior. The technique may utilize a surrogate model to complete a partial system where only a subset of the component values and/or the system response are specified. When the system response exhibits multiple modes (e.g., a same response for different input combinations), the disclosed may determine the input combinations for several modes. Using past simulation logs, the disclosed techniques may include searching over any subset of the variable inputs to improve the performance of a reference solution. The disclosed technique may also provide an explanation of the decision it makes for the different use cases.

### CROSS-REFERENCE TO RELATED APPLICATIONS

The present application claims priority to US Provisional Patent Application Nos.: 63/429,619, filed Dec. 2, 2022; 63/435,845, filed Dec. 29, 2022; and 63/460,153, filed Apr. 18, 2023, the contents of each of which are incorporated herein in its entirety.

### STATEMENT REGARDING FEDERALLY SPONSORED RESEARCH OR DEVELOPMENT

This invention was made with government support under Grant No. HR0011-19-S-0083 awarded by the Defense Advanced Research Projects Agency and Contract No. FA8750-20-C-0025 awarded by the U.S. Air Force. The government has certain rights in the invention.

### TECHNICAL FIELD

The present disclosure is drawn to human-artificial intelligence (AI) codesign, and specifically to techniques for completing a system about which a designer may only have partial information.

### BACKGROUND

Most system optimization techniques focus on finding the values of the system components to achieve the best performance. However, real-world systems often require searching in a restricted space for only a subset of component values while freezing some of the components to fixed values. Most methods are agnostic to the choice of the system inputs and care only about the final system performance. However, in real-world data, sometimes some features are missing. Handling uncertainty is crucial for stochastic decision-making like in stock markets and supply chain optimization. No known conventional optimization method completes a partially specified system, and no known conventional technique determines the confidence of the completed system.

### BRIEF SUMMARY

In various aspects, a method for partial system completion and/or optimization may be provided. The method may include learning a surrogate model from previous simulation logs of a system, where system inputs and responses are concatenated into a single vector, and a joint distribution is learned. The method may include using the surrogate model to predict any set of missing inputs from a partially specified system and/or predict a response from a partially specified system. A Gaussian Mixture Model (GMM) may be used to learn the surrogate model.

The method may include determining a probability density function of a completed system. The probability density function may be used as a measure of a confidence in any predicted missing inputs or predicted response, where a higher probability density function value indicates greater confidence.

The method may include searching over a space of variable components. Searching over the space of variable components may include using inverse design to generate a set of desired system responses to improve system performance. The surrogate model may be used to predict one or more possible system completions for each system response of the set of desired system responses. Each predicted possible system completion may act as a candidate solution. The method may include simulating the system with each candidate solution and using a response from simulating the system to update the surrogate model.

Searching over the space of variable components may include generating multiple possible values of one or more variable inputs for a given system response. Each value of the one or more variable inputs and the partially specified system may be considered a completely specified system. The method may include using the surrogate model to determine a probability density function of each completely specified system.

Searching over the space of variable components may include (i) using inverse design to generate a set of desired system responses to improve system performance; and (ii) generating multiple possible values of variable inputs for a given system response.

The method may include utilizing some of the partially specified system based on a value of the probability density function.

The method may include identifying a cause of anomalous behavior. Identifying the cause of anomalous behavior may include determining a probability density function of a given observation using the surrogate model, where a value below a threshold indicates the given observation is anomalous. The method may include determining a remedial action to be taken (e.g., based on the observation and the probability density function of one or more systems). Determining the remedial action may include: (i) assuming that a subset of inputs and response are missing, while a remainder set of inputs and response are specified; and (ii) sweeping over a plurality of combinations of the subset of inputs and response that are missing, where the remainder set of inputs and response are configured to act as a partially specified system, and predicting values of the subset of inputs and response that are missing and an associated probability distribution function value from the partially specified system. The method may include determining one or more predicted values of the subset of inputs and response that are missing is incorrect when the associated probability distribution function value is below a first threshold. The method may include replacing erroneous measurements with a predicted value from other measurements to ensure that a corrected system behavior lies within a distribution of past observations. The method may include using multiple system observations to break a tie based on a majority vote if different subsets of the plurality of combinations of the subset of inputs and response that are missing yield associated probability distribution function values above a second threshold.

In various aspects, a non-transitory computer readable storage medium is provided. The storage medium may contain instructions that, when executed by one or more processing units, causes the one or more processing units to, collectively, perform an embodiment of a method disclosed herein.

In various aspects, a system may be provided. The system may include one or more processing units operably coupled to an embodiment of a non-transitory computer readable storage medium as disclosed herein.

### BRIEF DESCRIPTION OF DRAWINGS

The accompanying drawings, which are incorporated in and constitute a part of this specification, illustrate embodiments of the present invention and, together with a general description of the invention given above, and the detailed description of the embodiments given below, serve to explain the principles of the present invention.

FIG. 1A is a flowchart of a method.

FIG. 1B is an illustration of a simplified system with inputs and responses.

FIG. 1C is an illustration of a concatenated vector.

FIG. 2A is a graph showing a simplified true function g(x).

FIG. 2B is a graph showing AIC score versus the number of GMM components.

FIG. 3A is a graph showing a comparison of g(x) evaluated at x_{predicted} corresponding to the highest pdf value at yₜₑₛₜ with the value of x computed using f( [symbol] ) (labeled exp.).

FIG. 3B is a graph showing g(x) evaluated at the top seven pdf values of x_{sweep} at yₜₑₛₜ. The highest pdf value is labeled pdf-1, next highest value pdf-2, and so on.

FIG. 4 is a schematic illustration providing an overview of the technique for different uses (partially specified system completion, partially specified system optimization, and data integrity check and error location/correction). Check marks indicate known values, question marks indicate unknown values, squares indicate fixed values, triangles indicate variable values, circles represent optimized values, and X indicates an erroneous value.

FIG. 5 is a flowchart of an example pipeline to complete a partially-specified system: the question marks show the unknown values of the system inputs/response, check marks shown known values of the system inputs/response, and circles indicate the predicted values. The pdf of the completed design is also shown.

FIG. 6A is an illustration showing generating a surrogate model from logged data.

FIG. 6B is an illustration showing possible completion of missing features (scaled) that are used when the pdf value at [symbol] computed using p( [symbol] | [symbol] ) is low; indicated columns denote possible completions (scaled value) of the partially specified system; the last column shows the pdf of possible system completions; the maximum pdf value is indicated.

FIGS. 7A and 7B are illustrations of candidate solution generation using inverse design (7A) and input sweep (7B).

FIG. 8A-8C are algorithms for generation of a desired system response (8A), obtaining candidate solutions using inverse design (8B), and obtaining candidate solutions by sweeping the variable inputs (8C).

FIG. 9 is a flowchart of a partially specified system optimization (Version 1).

FIG. 10 is a block diagram of a system.

FIG. 11A is a graph showing relative root mean squared error (rel-RMSE) based on a varying number of missing features.

FIG. 11B is a graph showing rel-RMSE based on a varying location of a single missing feature for a dataset of size 1050.

FIG. 12A is a graph showing input feature importance score for a first objective value.

FIG. 12B is graph showing different choices of the component values (y axis) for log (base 10) pdf values at the desired response (x axis).

FIG. 12C are graphs showing simulation of the candidate solutions from the top 250 pdf values that meet the constraints; the black dotted line shows the best system response observed from the simulation buffer. The pattern of the marker reflects a log value of the pdf.

FIGS. 13A and 13B are graphs showing partially specified system optimization with five variable system inputs, where 13A shows the non dominated front (NDF) of the solutions that dominate the reference solution (black circle) using the three versions of partially specified system optimization and the baseline version that uses the expected value (labeled Exp.) to generate candidate solutions; 13B shows the hypervolume versus the number of simulations.

FIG. 14 shows a graph of hypervolume versus #simulations for different methods.

FIG. 15 shows a graph of AIC score vs. #components in a GMM for a dataset size of 1000.

FIGS. 16A-16D are graphs showing partially specified system optimization with five variable inputs; 16A-16C show the NDF of the union of the solutions obtained using different partially-specified system optimization methods (the solution selected from the past simulation logs is shown using a black circle); 16D shows hypervolume versus #simulations for the different methods.

FIGS. 17A-17D are graphs showing partially specified system optimization using Ver-01 with five variable inputs corresponding to the top and bottom five features selected based on the importance score; 17A-17C show the NDF of the union of the solutions obtained using different partially-specified system optimization methods (the solution selected from the past simulation logs is shown using a black circle); 17D shows hypervolume versus #simulations for the different methods.

FIG. 18A is a graph showing AIC score versus #components for an unmanned underwater vehicle (UUV) example with a data (training+validation) size of 4,000 (optimum #components in the GMM is 22)

FIG. 18B is a graph showing possible error location, sweeping one missing feature at a time.

FIGS. 19A-19D are graphs relating to anomalies for four examples—Synchronous Optimal Pulse-width Modulation of Three-level Inverters (data size: 1050) (19A), Synchronous Optimal Pulse-width Modulation of Seven-level Inverters (data size: 1500) (19B), Multi-product Batch Plant (data size: 7000) (19C), and UUV (data size: 6000) (19D). The top row shows the percentage of times when the true error locations match (or lie within the top three) the predicted error locations among the data identified to have error. The middle row shows the RMSE between the predicted and true values of the erroneous features. The bottom row shows the percentage of data where the system fails to detect errors in the data.

FIGS. 20A-20F are graphs showing partially specified system optimization with different numbers of variable system inputs: 5 (20A-20B), 10 (20C-20D), and 20 (20E-20F). 20A, 20C, and 20E show the NDF of the solutions that dominate the reference solution (black circle) using the three versions of partially specified system optimization and the baseline version that uses the expected value (labeled Exp.) to generate candidate solutions. 20B, 20D, and 20F show the hypervolume versus the number of simulations.

FIG. 21 is an illustrated example of completing a partially specified system.

FIG. 22 is an illustrated example of detecting, locating, and correcting errors

It should be understood that the appended drawings are not necessarily to scale, presenting a somewhat simplified representation of various features illustrative of the basic principles of the invention. The specific design features of the sequence of operations as disclosed herein, including, for example, specific dimensions, orientations, locations, and shapes of various illustrated components, will be determined in part by the particular intended application and use environment. Certain features of the illustrated embodiments have been enlarged or distorted relative to others to facilitate visualization and clear understanding. In particular, thin features may be thickened, for example, for clarity or illustration.

### DETAILED DESCRIPTION

The following description and drawings merely illustrate the principles of the invention. It will thus be appreciated that those skilled in the art will be able to devise various arrangements that, although not explicitly described or shown herein, embody the principles of the invention and are included within its scope. Furthermore, all examples recited herein are principally intended expressly to be only for illustrative purposes to aid the reader in understanding the principles of the invention and the concepts contributed by the inventor(s) to furthering the art and are to be construed as being without limitation to such specifically recited examples and conditions. Additionally, the term, “or,” as used herein, refers to a non-exclusive or, unless otherwise indicated (e.g., “or else” or “or in the alternative”). Also, the various embodiments described herein are not necessarily mutually exclusive, as some embodiments can be combined with one or more other embodiments to form new embodiments.

The numerous innovative teachings of the present application will be described with particular reference to the presently preferred exemplary embodiments. However, it should be understood that this class of embodiments provides only a few examples of the many advantageous uses of the innovative teachings herein. In general, statements made in the specification of the present application do not necessarily limit any of the various claimed inventions. Moreover, some statements may apply to some inventive features but not to others. Those skilled in the art and informed by the teachings herein will realize that the invention is also applicable to various other technical areas or embodiments.

System design typically involves solving a constrained multi-objective optimization problem. The solution to this problem may be a set of component values that achieves the best performance. However, real-world system design often involves searching for only a subset of component values to optimize system performance. For example, when designing a lunar lander, the designer may wish to obtain the desired performance by only varying the controller design parameters, while keeping the other system parameters fixed. When searching for only a subset of the component values, the designer may still like to incorporate knowledge from past system behavior when all system component values were allowed to vary. In addition, associating a confidence measure with the set of candidate solutions to achieve the desired performance provides insight into the decision process. Finally, one may need a tool that automatically checks for data integrity. The tool should identify and correct anomalous observations.

Current optimization methods focus on finding all system component values to obtain the desired performance. When the search space is restricted to fewer components, the method needs to be rerun to search over only the subset of components. One may refer to an optimization that requires the selection of a subset of component values as a partially specified system optimization. This type of optimization arises in several contexts. For example, (1) supply chain issues may force a designer to restrict the choice of certain components to only available values, (2) changing some component values in a downstream design process may be too costly for an organization, (3) domain expertise or sensitivity analysis may determine the most promising component values to vary, and (4) when performing multiphysics simulations, the designer may want to vary the component values corresponding to faster simulations but still characterize the behavior of the complete system. When system design requires performing expensive simulations (e.g., for a large cyber-physical system), the designer may want insight into the decision process before performing costly experiments with a set of candidate solutions. When the system has the same performance for multiple choices of component values, the optimization methodology should identify the multiple sets (rather than just one solution) of component values that can achieve the specified response. Providing several combinations of component values allows the designer to select one over another based on prior preferences, e.g., system cost.

Designers may often have a good intuition about the design of a part of the system (perhaps based on legacy designs). They, however, may find a framework useful if it leverages the partially specified system to automatically predict the missing system component values and/or responses. Completing a partially specified system in this manner could enable human-artificial intelligence (AI) system co-design. Furthermore, real-world data often have error. A framework that not only detects errors, but also locates and corrects the features with errors may be helpful to downstream applications that use the data to make decisions.

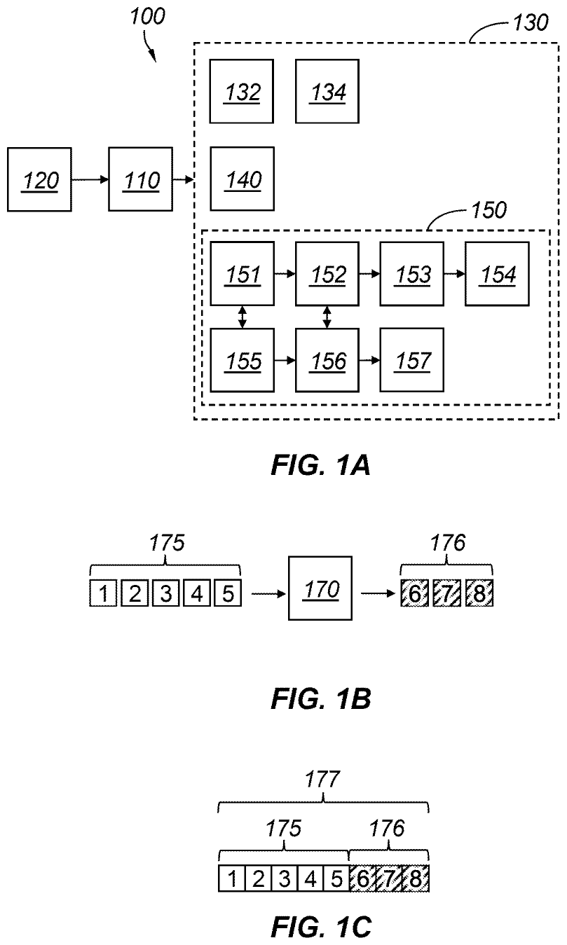

In various aspects, a method for partial system completion and/or optimization may be provided. Referring to FIG. 1A, the method 100 may include learning 110 a surrogate model from previous simulation logs. The method may include receiving 120 the previous simulation logs of a system (e.g., from a local non-transitory computer-readable storage device, transmitted over one or more networks, etc.). The surrogate model may take system inputs and responses, and concatenate them into a single vector, and a joint distribution is learned. This is illustrated in FIGS. 1B and 1C, where a system 170 is shown with inputs 175 and responses 176, and where a single vector 177 is shown concatenating the inputs and responses. Note that concatenation makes the surrogate model agnostic to the number of system inputs and the response—while FIGS. 1B and 1C shown five inputs (inputs 1, 2, 3, 4, and 5) and three responses (6, 7, and 8), there is not theoretical limit to the number of inputs or responses that could be included.

Any appropriate probabilistic model may be used to learn the surrogate model. In some embodiments, a Gaussian Mixture Model (GMM) may be used to learn the surrogate model. A GMM approximates the probability of the data using a finite number of Gaussian distributions. The probability density function (pdf) of a GMM with M components is denoted by p(x):

$$p ( x ) = {\sum }_{m = 1}^{M} {π}_{m} 𝒩 ( x : {μ}_{m} , {\sum }_{m} ) . \qquad ( 1 )$$

In Eq. (1), x represents the features (vector representing concatenated values of system inputs and the corresponding response in our case), and πₘ, μₘ, and Σₘ denote the weight, mean, and variance of the m^{th} component, respectively.

Probability distributions enable the estimation of conditional distribution when only a part of the data is specified. The conditional distribution of the missing features ( [symbol] ) in the data, given a set of present features ( [symbol] ), is obtained:

$$p ( {x}_{𝒫} ) = {\sum }_{m = 1}^{M} {π}_{m} 𝒩 ( {x}_{𝒫} : {μ}_{m , 𝒫} {\sum }_{m , 𝒫𝒫} ) \qquad ( 2 )$$

$$p ( {x}_{ℳ} \vert {x}_{𝒫} ) = {\sum }_{m = 1}^{M} {π}_{m , ℳ \vert 𝒫} 𝒩 ( {x}_{ℳ} : {μ}_{m , ℳ \vert 𝒫} , {\sum }_{m , ℳ \vert 𝒫} )$$

$${π}_{m , ℳ \vert 𝒫} = {π}_{m} 𝒩 ( {x}_{𝒫} : {μ}_{m , 𝒫} , {\sum }_{m , 𝒫𝒫} ) / p ( {x}_{𝒫} )$$

$${μ}_{m , ℳ \vert 𝒫} = {μ}_{m , ℳ} + {\sum }_{m , 𝒫ℳ}^{T} {\sum }_{m , 𝒫𝒫}^{- 1} ( {x}_{𝒫} - {μ}_{m , 𝒫} )$$

$${\sum }_{m , ℳ \vert 𝒫} = {\sum }_{m , ℳℳ} - {\sum }_{m , 𝒫ℳ}^{T} {\sum }_{m , 𝒫𝒫}^{- 1} {\sum }_{m , 𝒫ℳ}$$

$$f ( {x}_{𝒫} ) = E \{ {x}_{ℳ} \vert {x}_{𝒫} \} = {\sum }_{m = 1}^{M} {π}_{m , ℳ \vert 𝒫} ( {x}_{𝒫} ) {μ}_{m , ℳ \vert 𝒫} ( {x}_{𝒫} )$$

In Eq. (2), [symbol] and [symbol] are computed by indexing μₘ on the locations of the present and missing feature values of the given data instance. Similarly, [symbol] and [symbol] are computed by indexing Σₘ. The pdf of the present features is denoted by p( [symbol] ). Note that if we know all the feature values in a given data instance, p( [symbol] ) is the same as what is obtained in Eq. (1). The pdf of missing feature values, given the present feature values in the data instance, is computed by p( [symbol] | [symbol] ). The missing feature values as a function of the present feature values are determined by f( [symbol] ). The missing feature's value is the same as the expected value of [symbol] given [symbol] .

In a partially-specified system, [symbol] denotes a subset of the values of the specified system inputs and/or the response. The goal is to estimate the values of the missing inputs and/or the response ( [symbol] ) using [symbol] . When using an inverse design for partially-specified system optimization, [symbol] represents the values of the desired response and the fixed inputs.

f( [symbol] ) may be used to compute the values of the variable inputs ( [symbol] ). Once [symbol] is determined, the system is complete. One can use p(x) from Eq. (1) to compute the value of the pdf of the completed system.

The second search method sweeps over multiple possible values of the variable inputs and computes the pdf for each combination of variable inputs with [symbol] . The systems are complete once the values in [symbol] are specified, so one can compute the pdf value of the completed system either using p( [symbol] | [symbol] ) or simply using p(x). Using p( [symbol] | [symbol] ) is computationally expensive, as it needs matrix inversion. Therefore, one can use p(x) to compute the pdf value of the completed system when the values of the variable inputs ( [symbol] ). are specified. Except for a scaling factor, this simplification leads to no compromise in prediction when sweeping over the unknown feature values to determine the pdf of the complete system. The conditional pdf, p( [symbol] | [symbol] ) is replaced by p( [symbol] | [symbol] )/p( [symbol] ) where p( [symbol] ) denotes a fixed value for a partially specified system with [symbol] as the present features.

### Example 1

This simplified example illustrates model creation on a simple non-invertible function: g(x)=x*sin(x). One goal is to use a same GMM as a surrogate model to determine g(x) for a specified x or to computer the inverse, i.e., find multiple values of x for a specified g(x).

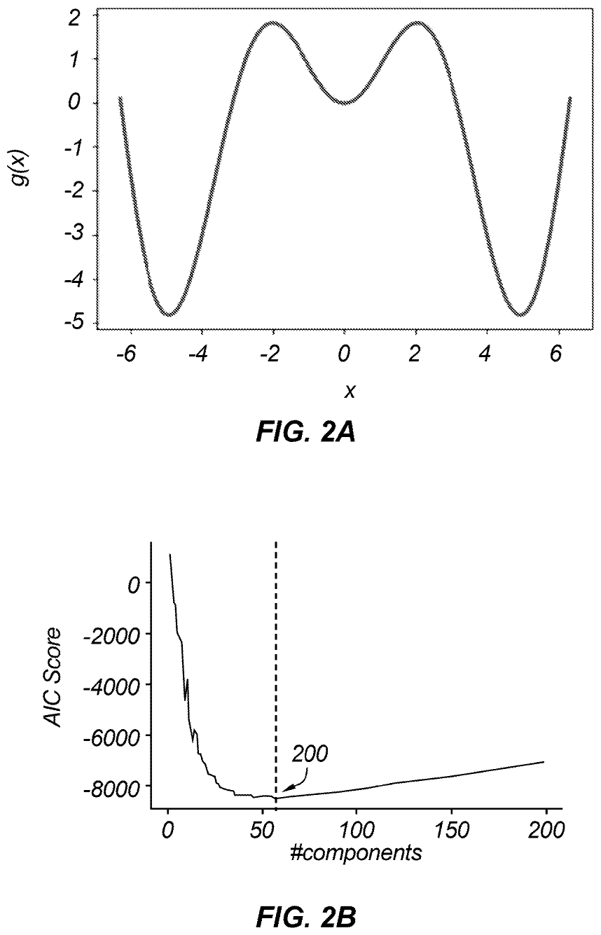

FIG. 2A shows g(x). In Table 1, Ex. 1-1 and Ex. 1-2 show different problems that can be solved using the same surrogate model. Ex. 1-3 shows the general case where one can estimate x from g(x) or vice versa. In Table 1, values listed as “?” are unknown values.

TABLE 1
(Examples of solving different problems)

| | | |
|---|---|---|
| Ex. 1-1 | Ex. 1-2 | Ex. 1-3 |

| x | g(x) | x | g(x) | x | g(x) |
|---|---|---|---|---|---|
| −6.04 | ? | ? | −4.79 | ? | −4.71 |
| −5.12 | ? | ? | −3.13 | −5.33 | ? |
| 0.17 | ? | ? | 0.85 | ? | 0.88 |
| 2.33 | ? | ? | 1.59 | ? | 1.65 |
| 5.71 | ? | ? | 1.81 | 5.75 | ? |

### Surrogate Model Creation

In this example, g(x) is evaluated at 1000 linearly spaced points in the range [−6.3,6.3]. Each of the 1000 points was concatenated with the value of g(x) at that point to obtain a matrix of size 1000×2. Next, the optimal number of GMM components is determined.

The number of components is varied in the [1,200) range and determine the Akaike information criterion (AIC) score for each component choice. The AIC score represents a tradeoff between model complexity (#parameters) and likelihood of fitting the data using the model. A lower #components leads to smaller model complexity, but less perfect data fit. In contrast to most machine learning methods that require tuning this hyperparameter by evaluating the performance on a separate validation fold, the disclosed approach does not need validation data. The AIC score minimum automatically ensures no overfitting on training data. FIG. 2B plots AIC score versus #components in the GMM. The time taken to sweep across all 200 possible components is 19.5 s on an AMD 7H12 Processor with 32 CPU cores. The least AIC score corresponds to the optimal 200 number of components (57 in this case, with an AIC score of −8464.05). This enables one to obtain p(x,g(x)), the joint distribution of x and g(x).

The method may include using the model to perform 130 one or more tasks. The method may include predicting 132 any set of missing inputs from a partially specified system and/or predicting 134 a response from a partially specified system. These predictions can be used to, e.g., ascertain the response of the system before performing system evaluation. Since the method predicts multiple system completions along with their confidence, a user may decide to use a solution with a higher confidence, if they want a particular level of certainty in the prediction. Thus, the method may include receiving a desired level of certainty, and automatically selecting a solution with at least that level of certainty. If the system evaluation is expensive or time consuming, the predictions can be used as a proxy to the system behavior.

The method may include determining 140 a probability density function of a completed system. The probability density function may be used as a measure of a confidence in any predicted missing inputs or predicted response, where a higher probability density function value indicates greater confidence.

The method may include searching 150 over a space of variable components. Searching over the space of variable components may include using inverse design to generate 151 a set of desired system responses to improve system performance. The surrogate model may be used to predict 152 one or more possible system completions for each system response of the set of desired system responses. Each predicted possible system completion may act as a candidate solution. The method may include simulating 153 the system with each candidate solution and using a response from simulating the system to update 154 the surrogate model.

Searching over the space of variable components may include generating 155 multiple possible values of one or more variable inputs for a given system response. Each value of the one or more variable inputs and the partially specified system may be considered a completely specified system. The method may include using the surrogate model to determine 156 a probability density function of each completely specified system.

Searching over the space of variable components may include (i) using inverse design to generate 151 a set of desired system responses to improve system performance; and (ii) generating 155 multiple possible values of variable inputs for a given system response.

The method may include utilizing 157 some of the partially specified system based on a value of a probability density function (e.g., from the determining 156 step).

### Example 2

Using Example 1 as a starting point, one can use p(x,g(x)) to predict g(x) given x. Forward mapping (x [symbol] g(x)) is an easy problem, since a given value of x yields a single value of g(x). One can generate a plurality of test samples by uniformly sampling the domain of g(x). In this example, 100 test samples (xₜₑₛₜ) were generated by uniformly sampling the domain of g(x): [−6.3,6.3]. These test points form the present features denoted by [symbol] in Eq. (2). The missing features ( [symbol] ) depict the unknown value of g(x).

One can estimate the value of g(x) at xₜₑₛₜ using two different methods: (1) using f( [symbol] ) from Eq. (2) to compute the expected value of the missing features given the present feature values, and (2) generating multiple possible values (y_{sweep}) of the function at each xₜₑₛₜ and using the one that maximizes the joint pdf value computed using p(x) from Eq. (1). Since the function values at xₜₑₛₜ are unknown, one can search over multiple possible function values (y_{sweep}). One can generate 1000 possible values of the function (y_{sweep}) at each xₜₑₛₜ by linearly sweeping in the range of the function g(x), i.e., [−4.82, 1.82]. When the test sample and the true function value match, the joint pdf s value will be high.

The log (base 10) value of the pdf computed using p(x) based on Eq. (1) can be generated, where the x axis shows the test sample, the y axis shows the possible values of g(x) at xₜₑₛₜ. Since each value in xₜₑₛₜ maps to a single value in g(x), the value of the pdf is high for a narrow band of values in y_{sweep}. Due to the nature (a given x maps to a single g(x)) of the mapping x [symbol] g(x), the estimated values using the two methods are close to each other. Indeed, a comparison of the actual value and the estimated value of the function g(x) at xₜₑₛₜ using the two methods results in, as expected, a nearly perfect overlap of the values. When using 1000 samples of xₜₑₛₜ (instead of 100), the resulting curves show a smoother coverage of the function. However, increasing either xₜₑₛₜ or y_{sweep} increases computation time, as one needs to determine the pdf value at each unique combination of xₜₑₛₜ and y_{sweep}. If one inverts the problem and try to estimate the value of x for a specified value of g(x), the expected value is no longer a good approximation of x, as shown next.

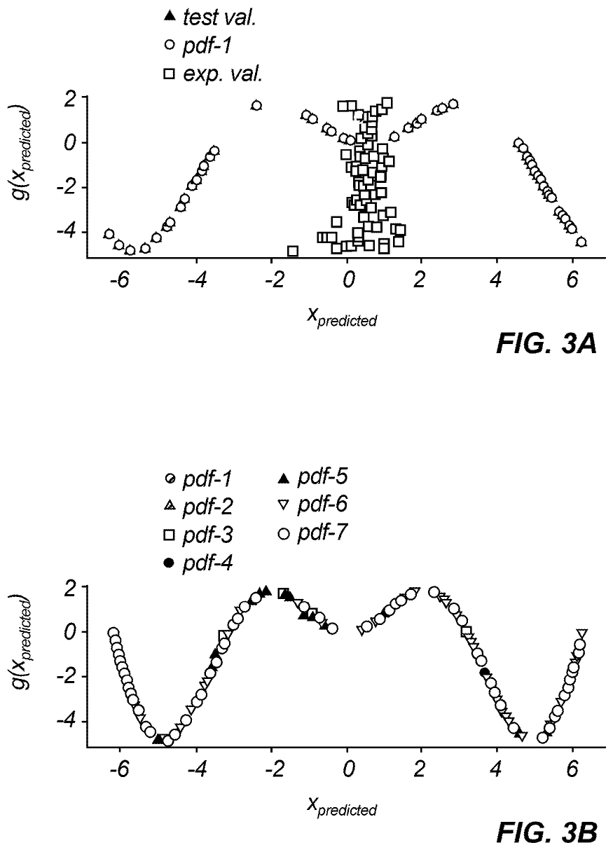

Now we approximate the inverse (see Table 1, Ex. 1-2) of a non-invertible function (g(x) [symbol] x). One can generate 100 test samples (yₜₑₛₜ) by uniformly sampling in the range of the function, i.e., [−4.82,1.82]. One can generate 1000 x_{sweep} values by linearly sweeping in the domain of the function g(x), i.e., [−6.3,6.3]. The aim is to determine the possible values of x that correspond to specified values in yₜₑₛₜ. As before, one can approximate the inverse using the two methods. In contrast to the earlier case, there are several possible inverse map values for a given sample from yₜₑₛₜ. All possible x_{sweep} values that have a high pdf value at a given value from yₜₑₛₜ constitute the estimated values of the inverse map. FIG. 3A shows the value of g(x) at the predicted value of x (x_{predicted}) using the two methods. We observe that the evaluated value of g(x) at x_{sweep} corresponding to the highest pdf value is very close to yₜₑₛₜ. However, g(x) evaluated at x_{sweep} computed using f( [symbol] ) in Eq. (1) is far off from yₜₑₛₜ. Estimating the inverse using the expected value fails when the mapping is many-to-one.

Next, one can answer the question: how good is the estimate of the inverse for a many-to-one mapping?One can extract the top seven pdf values at each yₜₑₛₜ. One can evaluate g(x) at x_{sweep} corresponding to these top seven pdf values, as shown in FIG. 3B. Note that a larger coverage of g(x) obtained than that obtained using just the maximum value of the pdf. The example illustrates a novel and flexible method for approximating a function in both directions (x ↔g(x)), using the same surrogate model.

The example also illustrates the robustness of the disclosed technique to uncertainty. Most machine learning methods can only handle small uncertainties in system response, e.g., limited to a small perturbation like the addition of Gaussian noise. In contrast, the disclosed approach is agnostic to the amount of uncertainty. For example, at yₜₑₛₜ=−3, the example could successfully predict responses whose sign is flipped (−4 and +4) or an uncertainty of 200%!

The disclosed techniques can be used to perform various tasks. For example, one can use the disclosed techniques to (1) complete a partially specified system, (2) optimize a system by searching over only a subset of the components, and/or (3) check the integrity of observed data, identify the error location, and correct the error.

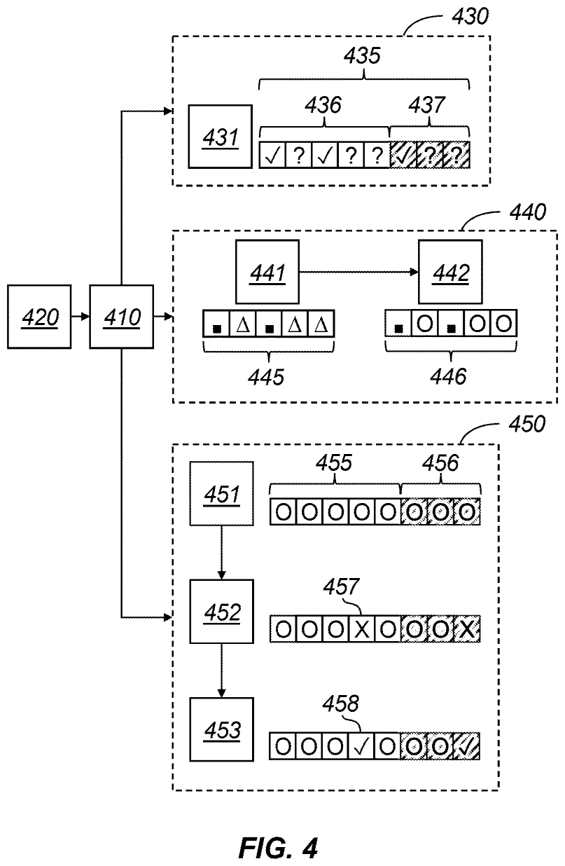

FIG. 4 shows the three use cases, each enclosed in a dotted box. One can use past system behavior 420 (input values and the corresponding response) to learn the GMM-based surrogate model 410. One can then use the same surrogate model to for partial system completion 430. Completing a partial system 431 may include determining any set of missing feature values (question marks) given the present feature values (check marks). Here, feature 435 refers to the system inputs 436 and the corresponding system response (i.e., objectives/constraints) 437. The present feature values ( [symbol] ), correspond to the values in the partially specified system and the missing feature values ( [symbol] ) denote the unknown values of the system inputs and/or response.

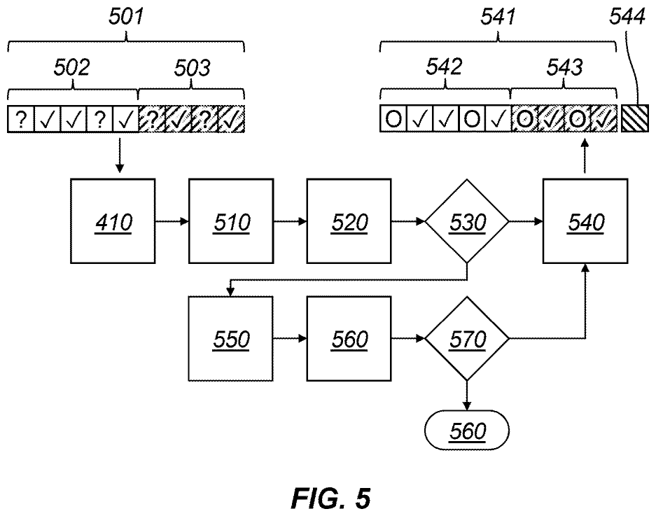

Referring to FIG. 5, a flowchart of an example of completing a partially specified system can be seen. Provided with a partial specified system 501 (which includes inputs 502 and responses 503) are received by the surrogate model 420. The method may include determining 510 [symbol] using f( [symbol] ). The method may include using 520 p(x) to compute the pdf. The method may include comparing 530 the pdf to a threshold value (e.g., determining if this is a “low pdf”).

In some embodiments, the threshold used to determine a “low” pdf is a mean pdf value of the lowest 10% of the pdf values of the training data. In some embodiments, the threshold is a value one (or at least one) order of magnitude lower than a mean pdf value of the lowest 10% of the pdf values of the training data. In some embodiments, the threshold is a value two (or at least two) orders of magnitude lower than a mean pdf value of the lowest 10% of the pdf values of the training data. In some embodiments, the threshold is a value lower than the lowest pdf value of the training data. In some embodiments, the threshold is a value lower than an order of magnitude lower than the lowest pdf value of the training data. In some embodiments, the threshold is a value lower than two orders of magnitude lower than the lowest pdf value of the training data.

If the pdf is not a low pdf (e.g, above the threshold, or at least as large as the threshold), the method may include defining 540 the missing estimate(s) equal to [symbol] , and outputting a completed system 541 (including inputs 542 and responses 543), and optionally the pdf 544 as well.

If comparing 530 the pdf indicates that the pdf is a low pdf, however, the method may include sweeping 550 combinations of

$${x}_{M}^{s w}$$

and computing p(x) as disclosed herein. The method may include determining 560 the highest pdf and the corresponding input from

$${x}_{M}^{s w} .$$

The method may include comparing that highest pdf to a threshold (which may be the same threshold used in the comparing 530 step, or may be a different threshold) to determine if the pdf is a “low pdf”. Again, if the pdf is not a low pdf, the method moves to the defining 540 step. If the pdf is a low pdf, the completion process may fail 570.

### Example 3

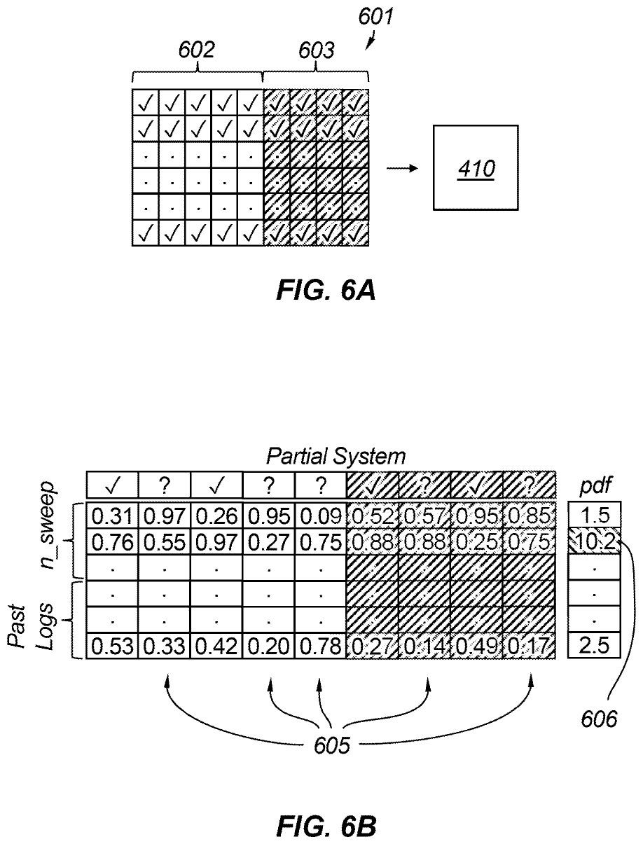

As noted above, FIG. 5 shows the pipeline for completing a partially specified system. In this example, all the computations (in all presented methodologies) are performed after scaling the values (system inputs/response) to lie in the [0,1] range. Referring to FIG. 6A, in the example, a surrogate model 410 (GMM) is learned based on past system behavior 601. The GMM is trained on the concatenated values of the past system inputs 602 and the corresponding response 603. The number of components in the GMM are varied, and the one with the least AIC score on the training data is used. Given a partially specified system with some specified feature values (inputs and/or response), f( [symbol] ) from Eq. (1) is used to compute the missing values ( [symbol] ) using the present feature values ( [symbol] ). Once [symbol] is determined, the system is complete. p(x) from Eq. (2) is used to compute the pdf of the complete system, x=[ [symbol] , [symbol] ]. A high pdf value indicates high confidence in the predictions and the system is now complete.

A low pdf value indicates that no (or very low) confidence in the prediction, as x does not lie within the learned distribution using the past system behavior. In such a scenario, one can sweep over multiple possible values of [symbol] and determine the pdf at each swept value. See FIG. 6B. For example, one can generate n_sweep samples using Latin hypercube sampling (LHS) within the concatenated bounds of the system inputs and the response. One can append the past simulation logs to these samples. Given a partially specified system, one can use the values from these samples at indices (column(s) 605 in FIG. 6B) corresponding to the missing values in the partially specified system. Thus, one can generate several possible completions of the system.

Then, one can select the best value of [symbol] among the several options. One can compute the pdf value for all possible system completions. One can select the most confident completion, i.e., the completion with the highest pdf value (pdf value 606 in FIG. 6B).

If the pdf value for the most confident completion is above a threshold (e.g., “pdf_low_thresh”), the model has obtained the complete system. If the designer is interested in determining multiple possible competitions, one can return the completions corresponding to top few pdf values. For example, the top 2, the top 3, the top 4, the top 5, the top 6, or the top 7, the top 8, the top 9, or the top 10 pdf values. If the pdf value is low for all possible system completions, the system completion method fails.

One way to overcome this failure is to repeat the procedure with a larger number of values for possible system completions, i.e., by increasing n_sweep. Increasing n_sweep leads to higher precision in the possible values assigned to the missing features at the cost of more computation.

Referring to FIG. 4, the model can also be used for partially specified system optimization. For example, a designer may specify a reference solution 445 that needs improvement, the values of the fixed system inputs (squares), and the variable inputs (triangles). Here, one can actively learn and update the surrogate model to predict the values of the variable inputs to improve system performance. One can simulate the system with the predicted values of the inputs (candidate solutions), update the surrogate model with new observations, and repeat the process until performance saturation. Thus, after searching 441 over the variable components in the reference solution 445, the model can output 442 an optimized partial system 446, where circles represent the optimized values of the variable inputs.

### Example 4

One can build upon the partially specified system completion method to optimize a partially specified system. In a partially specified system optimization problem, some of the system inputs have fixed values (check marks in FIG. 6B) while the values of the rest of the inputs can vary (question marks in FIG. 6B). A system designer determines which inputs have fixed values. The aim in this example is to improve the performance of a reference solution by searching over values of only the variable system inputs. During optimization, one can also use the information from past system behavior (when all input values are allowed to vary) that is stored in a buffer. One can search for candidate solutions (values of the variable inputs) in two different dimensions: (1) specifying multiple desired system responses to improve the system performance and finding the candidate solution for each specified response, and (2) searching over multiple possible values of the variable inputs for a given system response. The combination of the two search methods is useful. One can determine the pdf value of the completed system (after determining the variable input values) and assign a confidence level to the candidate solutions. One can simulate the system with some of the top candidate solutions selected using the pdf values and update the surrogate model with the new system responses. One can repeat the process until the performance saturates.

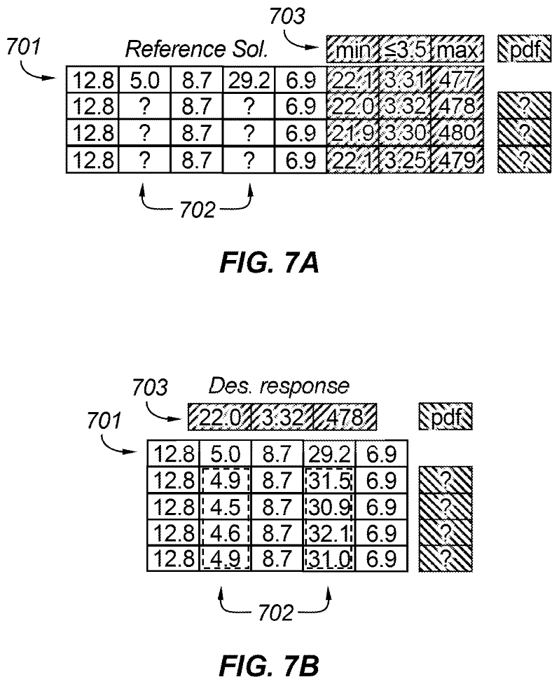

FIGS. 7A and 7B shows an example of partially specified system optimization of the reference solution 701. The variable inputs are in the indicated column(s) 702. FIG. 7A illustrates partially specified system optimization based on inverse design to generate candidate solutions. The values 703 of the desired response are indicated with right to left hatched columns (with headers “min”, “≤3.5”, and “max”) to improve the performance of the reference solution in all performance metrics. The specified responses meet the constraints and are at least as good or better than the reference solution in other performance metrics. One can use f( [symbol] ) from Eq. (2) to determine [symbol] for each desired response. As we specify the value of the desired response, [symbol] consists of the values of the fixed system inputs and the specified response. After determining the value of [symbol] , the result is a complete system at each specified response. One can compute the pdf value of all the completed systems.

FIG. 7B shows the search for multiple candidate solutions for a specified value 703 of the system response. One can generate multiple possible values for [symbol] as possible completions of the partially specified system. One can ensure that the possible values of [symbol] are within the search space of the corresponding system inputs. One can compute the pdf value of each completed system. Finally, one can select a few of the most promising candidate solutions determined by their pdf value. A high pdf value corresponds to a more confident candidate solution (or exploitation), while a low pdf value is akin to exploration.

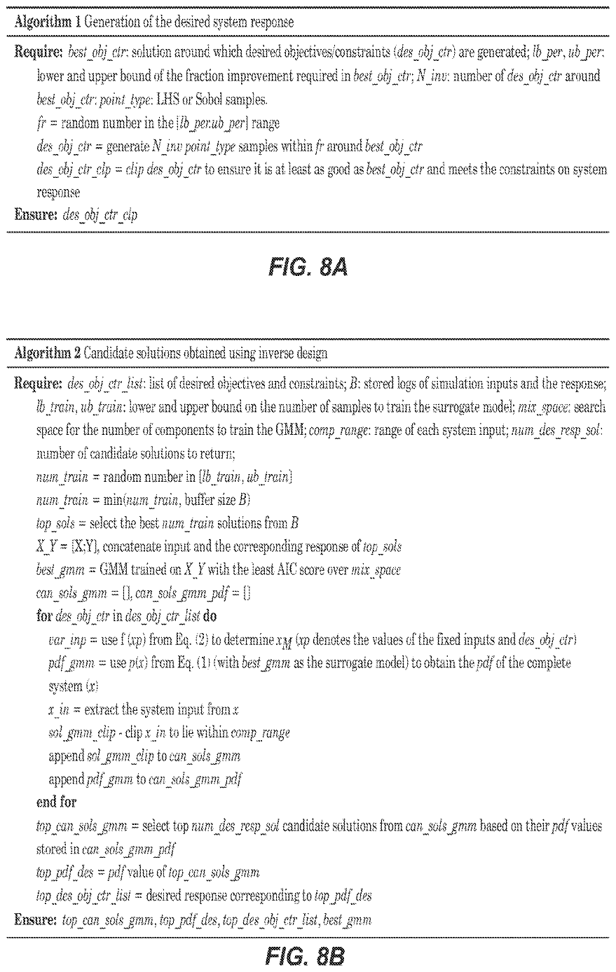

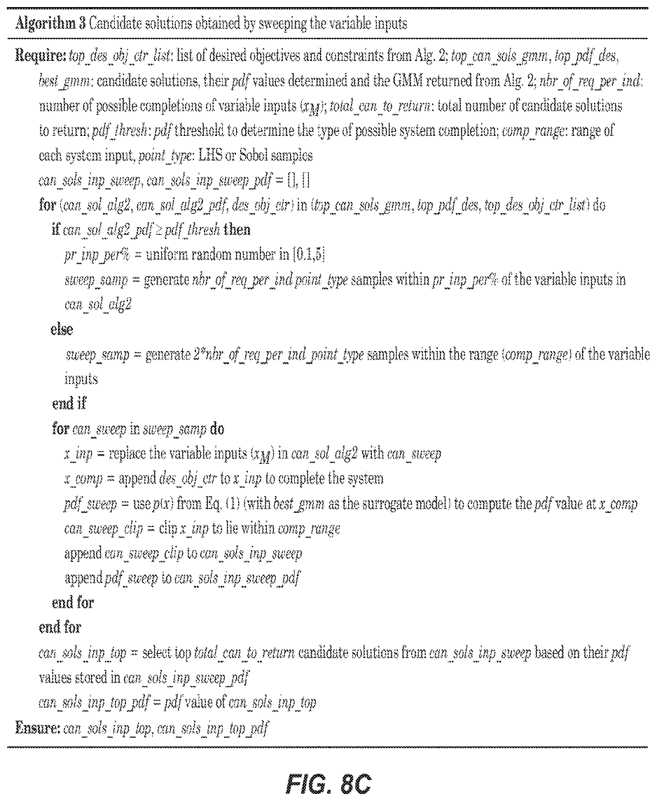

Alg. 1 (FIG. 8A) presents a method to generate the desired system response (i.e., objectives/constraints) in order to enhance system performance [28]. We generate N_inv desired system responses (des_obj_ctr) to improve the performance of a reference solution best_obj_ctr. The aim is to improve the performance of the reference solution by a fraction (fr), generated randomly in the [lb_per,ub_per] range. The algorithm may use, e.g., either Sobol or LHS samples around best_obj_ctr to generate des_obj_ctr. One can clip the desired response (des_obj_ctr_clp) to satisfy all the constraints on system response. One can ensure that des_obj_ctr_clp is better or at least as good as best_obj_ctr. One can use des_obj_ctr_clp to generate candidate solutions through inverse design.

Alg. 2 (FIG. 8B) describes a procedure to generate candidate solutions using inverse design. The process may include selecting num_train past system inputs and the corresponding response from the buffer (B) to train the surrogate model. The process may include setting num_train to a random number generated in the [lb_train,ub_train] range. If num_train is less than the cardinality of B, the process may use the entire buffer. Otherwise, the process may include selecting all the simulations from B that meet the constraints on the response and have the best values of the objective function. If more data is needed, the method may include using the simulations with the least constraint violation (summed if there are multiple constraints) of the desired system response. Next, the method may include concatenating the num_train system inputs and the corresponding response (X_Y) to train the surrogate model. The method may include determining the number of GMM components from mix_space with the least AIC score on X_Y (best_gmm). The method may include iterating over the desired system response (des_obj_ctr) from des_obj_ctr_clp (generated using Alg. 1) to improve system performance. The method may include setting [symbol] to the values corresponding to the fixed system inputs and des_obj_ctr. The method may include using f( [symbol] ) to determine the values of the variable system inputs (var_inp= [symbol] ). The result being a complete system, x. One can use p(x) to compute the pdf value (pdf_gmm) of the completed system. One can store the pdf value in can_sols_gmm_pdf. The method may include extracting the input part (x_in) from the completed system, x. The method may include clipping x_in (sol_gmm_clip) to lie within the range (comp_range) of system inputs. The method may include storing sol_gmm_clip in can_sols_gmm. The method may include selecting the top candidate solutions (top_can_sols_gmm) from can_sols_gmm based on the pdf values stored in can_sols_gmm_pdf. Finally, The method may include returning top_can_sols_gmm, the corresponding pdf values (top_pdf des), the desired response (top_des_obj_ctr_list), and the GMM (best_gmm).

Alg. 3 (FIG. 8C) generates candidate solutions by searching over multiple possible values of the variable inputs. The method may include iterating over the candidate solutions (can_sol_alg2) generated using Alg. 2. If the pdf value (can_sol_alg2_pdf) of can_sol_alg2 is above a threshold (pdf_thresh), the method may include searching for more candidate solutions in the neighborhood of can_sol_alg2. The method may include generating nbr_of_req_per_ind point_type samples (sweep_samp) within pr_inp_per % of the variable inputs in can_sol_alg2. The method may include setting pr_inp_per % to a random number in a target range (here, the [0.1,5] range). A low value (below pdf_thresh) of can_sol_alg2_pdf indicates low confidence in the system obtained using the candidate solution. Hence, the method may include increasing the search space over which one looks for more candidate solutions for the given des_obj_ctr. The method may include generating 2×nbr_of_req_per_ind point_type samples (sweep_samp) within the entire range of the variable system inputs. sweep_samp denotes possible values of the variable system inputs. These sweep_samp values, in conjunction with the desired response (des_obj_ctr), and the fixed system input values depict possible system completions. Next, the method may include replacing the variable inputs in can_sol_alg2 with each possible value of the variable inputs (can_sweep) from sweep_samp to obtain the system input x_inp. The method may include appending the desired response (des_obj_ctr) to x_inp to obtain the complete system with the inputs and response (x_comp). The method may include using the GMM (best_gmm) obtained using Alg. 2 to compute the pdf value of the completed system (pdf sweep). The method may include clipping x_comp (can_sweep_clip) to lie within the range of the system inputs (comp_range). The method may include storing can_sweep_clip in can_sols_inp_sweep and the corresponding pdf value in can_sols_inp_sweep_pdf. The method may include selecting total_can_to_return top candidate solutions (can_sol_inp_top) based on the pdf value of the completed system stored in can_sols_inp_sweep_pdf. The method may also include returning the pdf values (can_sols_inp_top_pdf) of the selected candidate solutions.

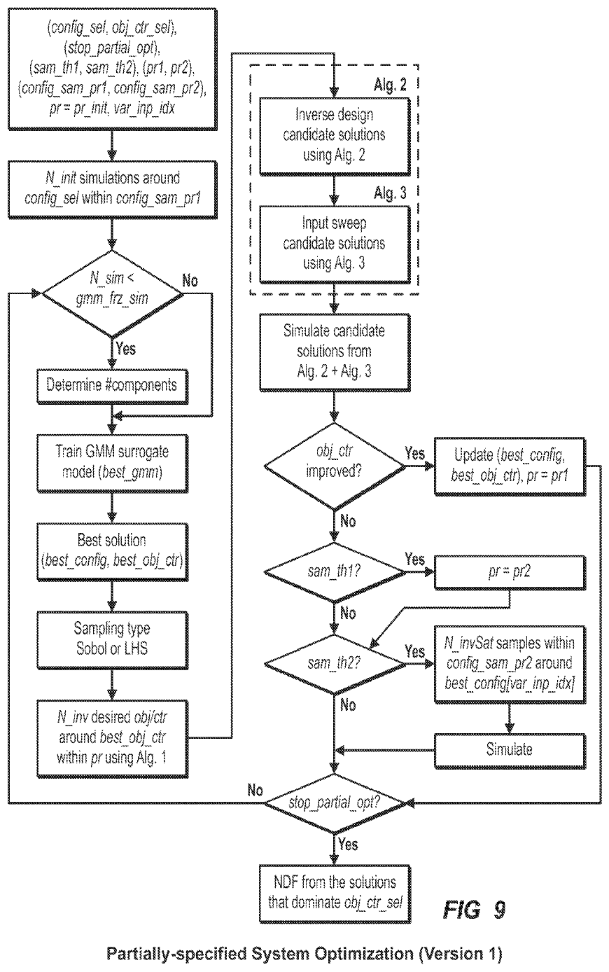

A combination of Alg. 2 and Alg. 3 may be used to perform partial system optimization. FIG. 9 shows an example flowchart. One can use the past simulation logs and select a solution to enhance the performance of the selected solution. In the flowchart, config_sel represents the input of the selected solution from the stored buffer (whose performance needs to be improved) and obj_ctr_sel represents the corresponding objectives/constraints, i.e., the system response. The method may include aiming to enhance system performance by searching over values for only a subset of the variable system inputs with indices var_inp_idx. The method may include generating N_init samples within config_sam_pr1% of config_sel to explore the neighborhood of the selected solution, config_sel. The method may include using the past simulation logs to determine the best GMM (best_gmm), i.e., #components with the least AIC score. The method may include determining the number of GMM components only if #simulations during partially specified system optimization is less than gmm_frz_sim. Otherwise, if #simulations exceeds gmm_frz_sim, the method may include using the GMM components obtained when #simulations was less than gmm_frz_sim. Freezing #components speeds up training of the surrogate model by avoiding search over all possible choices of component values. The method may include updating the GMM as more system responses are gathered during optimization. The method may include using Alg. 1 to generate N_inv desired responses (i.e., objectives/constraints) to improve performance by pr % in all the metrics. Here, pr=100×fr (Alg. 1). The method may include alternating the choice (point_type) of the inverse design candidate solutions generated in Alg. 1 between, e,g., LHS and Sobol samples, at each successive iteration of partially-specified system optimization. Similarly, the method may include alternating the choice of sweep_samp in Alg. 3 between, e.g., LHS and Sobol samples. Here, an iteration refers to a complete cycle of partially specified system optimization: generation and simulation of candidate solutions. One can use Alg. 2 and Alg. 3 to generate multiple candidate solutions. The method may include simulating the candidate solutions derived using the two algorithms. If the system performance improves, the method may include updating best_config and best_obj_ctr to the improved solution. If the performance does not improve for sam_th1 iterations, the method may include lowering the desired improvement in performance (pr) to pr2. If the performance improves, the method may include resetting pr to pr1. If the performance does not improve for sam_th2 iterations, the method may include generating and simulating N_invSat candidate solutions within config_sam_pr2% of the values of the variable inputs (var_inp_idx) corresponding to the best solution. The method may include terminating a partially specified system optimization upon meeting some stopping criteria (stop_partial_opt) specified by the designer.

The partially specified system optimization method discussed above may be referred to as “Version 1”. Also considered are two variations of Version 1 called Versions 2 and 3. In Version 2, the method includes initially only running Alg. 2. Upon observing a saturation in system performance over some iterations, the method includes switching to Version 1 (i.e., generating candidate solutions using Alg. 2 and Alg. 3). Starting only with Alg. 2 allows fast exploration using inverse design and switching to complete exploration only when the performance saturates.

In Version 3, the method includes searching for candidate solutions by sweeping over the values of the variable inputs only when the performance saturates. Searching for the candidate solutions begins using only Alg. 2. Version 3 also includes reducing the number (N_inv) of desired objectives/constraints and return all (instead of just selecting the top num_des_resp_sol based on the pdf values) the candidate solutions from Alg. 2. Upon observing a saturation in performance over some iterations, the method includes switching to Version 1. Once a performance improvement is observed, the method may include reverting to searching for candidate solutions using Alg. 2.

Referring to FIG. 4, the model can also be used for data integrity checks. Provided 451 an observed data instance (including inputs 455 and outputs 456), the disclosed technique can detect and identify 452 an anomaly by detecting a change in the distribution of an observation. Then it identifies the location of the anomalous behavior (X symbols, such as error 457). Identifying the cause of anomalous behavior may include determining a probability density function of a given observation using the surrogate model, where a value below a threshold indicates the given observation is anomalous.

The method may include determining 452 a remedial action to be taken or a corrected behavior (e.g., based on the observation and the probability density function of one or more systems). Determining the remedial action may include: (i) assuming that a subset of inputs and response are missing, while a remainder set of inputs and response are specified; and (ii) sweeping over a plurality of combinations of the subset of inputs and response that are missing, where the remainder set of inputs and response are configured to act as a partially specified system, and predicting values of the subset of inputs and response that are missing and an associated probability distribution function value from the partially specified system. The method may include determining one or more predicted values of the subset of inputs and response that are missing is incorrect when the associated probability distribution function value is above a first threshold. The method may include replacing erroneous measurements with a predicted value from other measurements to ensure that a corrected system behavior lies within a distribution of past observations. The method may include using multiple system observations to break a tie based on a majority vote if different subsets of the plurality of combinations of the subset of inputs and response that are missing yield associated probability distribution function values above a second threshold.

### Example 5

An example procedure to locate and correct a single error in x is considered. Suppose x represents the features (concatenated values of the input and the response) of a given data instance. First, one can use p(x) from Eq. (1) to compute the pdf value of the system at x. If p(x) is low, an error can be flagged, as the observation is out of the probability distribution of the learned surrogate model. If an error is flagged, one can use the procedure below to locate and correct a single error in x.
(1) Sweep over the features in x one at a time. Suppose the value of the swept feature (i) is missing. Let [symbol] represent the ith missing feature. The values of the remaining features (i.e., values of all features, except the ith feature value) in x act as present features, [symbol] .
(2) Use f( [symbol] ) to predict the value of the ith feature, i.e., the value of [symbol] .
(3) Replace the value at the index (i) corresponding to the missing feature in x with the predicted value of [symbol] computed using f (xP). Call the new system

$${x}_{r e p l a c e}^{i} .$$

(4) Compute the pdf value of the new system at

$${x}_{r e p l ace}^{i} , i . e . , p ( {x}_{r e p l a c e}^{i} ) .$$

(5) Repeat Steps 1-4 for all the features in x.
(6) Determine the feature (i^{max}) from the different missing feature choices that produces the highest value of

$$p ( {x}_{r e p l a c e}^{i} ) .$$

If the value of

$$p ( {x}_{r e p l a c e}^{i} )$$

at i^{max} is above a threshold pdf_thresh_err, the new distribution now lies within the distribution learned by the surrogate model. Therefore, one has located the error to feature i^{max}. One can replace the value of i^{max} with the predicted value using all other features, except i^{max}.

The above procedure can be extended to locate and correct more than one error as well. As earlier, one can first compute p(x) to determine if there is an error in the observation. If there is a failure to detect (none of the values in

$$p ( {x}_{r e p l a c e}^{i} )$$

are above a threshold) any single error using the above procedure, it is likely that the system has two or more errors. Next, one can sweep all possible combinations of values of two features at a time from x and repeat the above process. The combination that produces the highest pdf value indicates the error locations. One can ignore the observed feature values at these locations and replace them with the predicted values from all other features (i.e., all features except the combination of features with error).

The method may include displaying one or more graphs to a designer. The graphs may include, e.g., different choices of the component values (y axis) for pdf values (such as log(base 10) pdf values) at the desired response (x axis), or candidate solutions from a predetermined number of the best pdf values that meet the constraints of a system.

In various aspects, a system may be provided. Referring to FIG. 10, a system may include one or more processing units 1000 operably coupled to a non-transitory computer readable storage medium 1010. The storage medium may contain instructions that, when executed by one or more processors, causes the one or more processors to, collectively, perform an embodiment of a method as disclosed herein.

As used herein, the term “processing unit” is intended to refer to any electronic device capable of processing, receiving, or transmitting data or instructions. For example, the processing unit ray be a microprocessor, a central processing unit (CPU), an application-specific integrated circuit (ASIC), a digital signal processor (DSP), or combinations of such devices. As described herein, the term “processing unit” is meant to encompass a single processor or processing unit, multiple processors, multiple processing units, or other suitably configured computing element or elements. Processing unit may refer to a processor core, a CPU, a strand, an instruction execution pipeline, or other such processing component within a processor.

The processing unit(s) may also be coupled to, e.g., a memory 1020, a transceiver 1030 (e.g., for wired or wireless communications), and/or an input/output interface(s) 1040 (e.g., for connecting to a keyboard, display, etc.). The processing units may be within a first housing 1050. In some embodiments, the processing unit(s) may be configured to communicate with one or more remote processing unit(s) 1065 (e.g., located in a remote housing 1060). For example, a processor in one server cabinet may be configured to cooperate and communicate with a processor in a second server cabinet.

In some embodiments, the remote processing unit(s) may be configured to receive input from a user (e.g., a designer) and communicate with the processing unit(s) performing the disclose operation.

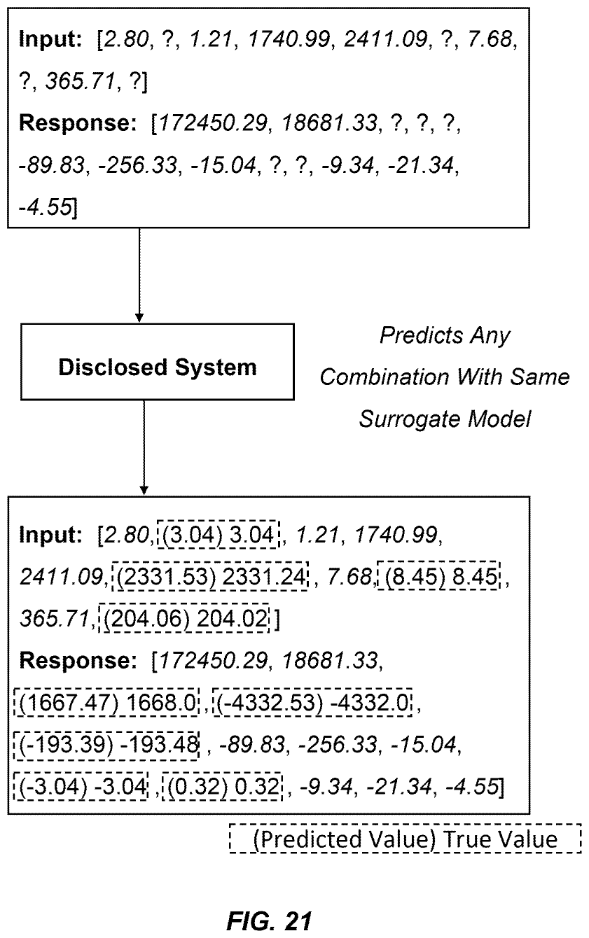

In various embodiments, the disclosed techniques can improve a system's performance (e.g., an inverter). It can use a reference solution as a starting point and improve its quality further using inverse design. The disclosed technique explores multiple modalities of the search space that lead to a similar system response. The disclosed method also assigns confidence to the solutions. One could use the high confidence samples to have a certainty in improvement in performance. The disclosed method also completes a partially specified system (see FIG. 21). Completion of missing information may be helpful in real-world settings where the system uses values from different sensors as an input. If some sensor stops transmitting information, the disclosed method can be used to estimate the values of the missing sensors. The confidence assigned to the completion can be used to assess the trust in the prediction of the missing information. The disclosed method can also aid the designer when trying to adjust a subset of component values to achieve a desired response. A designer can specify a desired output and specify the locations of the variable inputs. The disclosed method can determine the values of the variables inputs that can achieve the desired output. It also assigns confidence to the variable inputs.

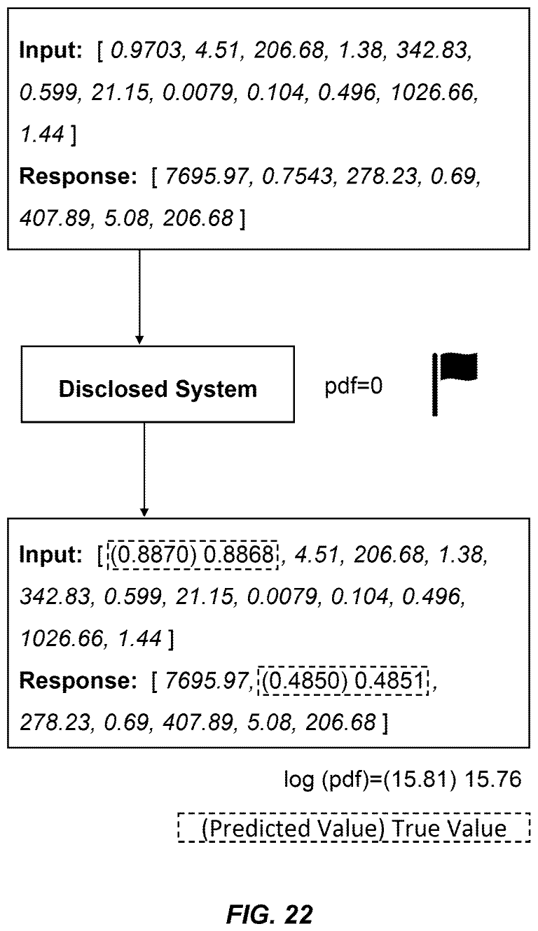

The disclosed method can also detect, locate, and correct errors (see FIG. 22). It can first check the integrity of the inputs applied to the system. Upon detecting an anomaly in the inputs, it can detect the location of the anomaly, and correct the values of the features with error. Thus, the system can operate despite the presence of incorrect inputs (from sensors). It can even help in diagnosis, thus reducing the repair time by pinpointing the location of the error.

Example implementations for real-world problems, below, utilize an embodiment of the above disclosed method, using Sci-kit learn, PyGMO, and PyMOO for implementations.

### Example 6 (Synchronous Optimal Pulse-Width Modulation of Three-Level Inverters)

This problem has two objectives (minimization of both), 24 constraints (all ≤0) on the system response, and 25 decision variables or system inputs. The NSGA-II implementation from PyMOO is used to generate the past simulation logs. A population size of 200 individuals was used, and these individuals were evolved over 100 generations. Other parameters are set to their default values. A solution from the non-dominated front (NDF) of the two objectives was selected (that meets the constraints) and its performance was enhanced by searching over a subset of system inputs while keeping the values of the rest of the inputs fixed.

Next, for partially specified system completion, a portion of the unique simulations from the logged data that satisfy the constraints on system response was used. A five-fold cross-validation was performed on the selected data: use 80% of the data to train the surrogate model and perform partially-specified system completion on the remaining 20% validation set. The process was repeated for all five folds. The best #components for the GMM were determined by varying the components in the [1,200) range and using the one with the least AIC score on the training set. The GMM was trained on the concatenated values of the system inputs and the corresponding response. The concatenated data instance has a dimension of 51 (25 system inputs+2 objectives+24 constraints). In a real-world scenario, with a continuous stream of data, the designer can update the GMM by training on new data instances and use the updated model to complete the partial systems. Updating the model will allow it to adapt to changing data instances, similar to active learning.

Partially-specified systems are synthesized using the data in the validation set. Values of some of the inputs and/or the system response from the data in the validation set are randomly masked. The number of masked-out features (inputs and/or response) are varied from 1 to 47 in steps of 2. For example, in one setup, 17 features were masked out of 51 features. Three partially-specified systems were generated for each data instance in the validation set. The 17 masked indices (inputs and/or response) were randomly selected. The masked indices act as locations of the missing features ( [symbol] ). The present features ( [symbol] ), i.e., non-masked indices, correspond to the values of the partially-specified system. The values of xM were predicted using the partially-specified system completion methodology disclosed in Example 3. The process was repeated for each choice of the number of missing features. f( [symbol] ) from Eq. (2) is used to determine [symbol] . [symbol] and [symbol] are used to determine the pdf value (Eq. (1)) of the completed system at x=[ [symbol] , [symbol] ]. If the pdf value was low, multiple possible values of [symbol] were swept over. LHS was used to generate 10,000 possible values of [symbol] . Possible values of xM corresponding to input features were generated, and it was ensured that the values lied within the range of the system inputs. As the range of the system response varies, its bounds were set to the min/max values of the system response observed in the training set. The training data was appended to the generated samples as possible values of [symbol] to take advantage of the available information (see FIG. 6B).

As will be understood, a designer can increase the number of samples beyond 10,000 for a more precise sweep at the cost of longer compute time to evaluate the pdf value at each sample. A larger number of samples may be helpful when the system needs a large number of features to cover the entire search space.

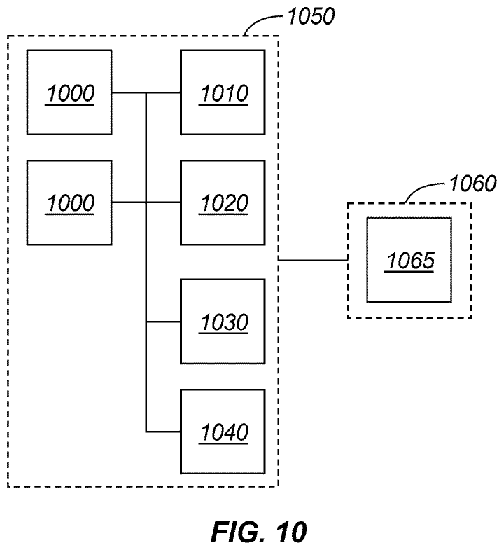

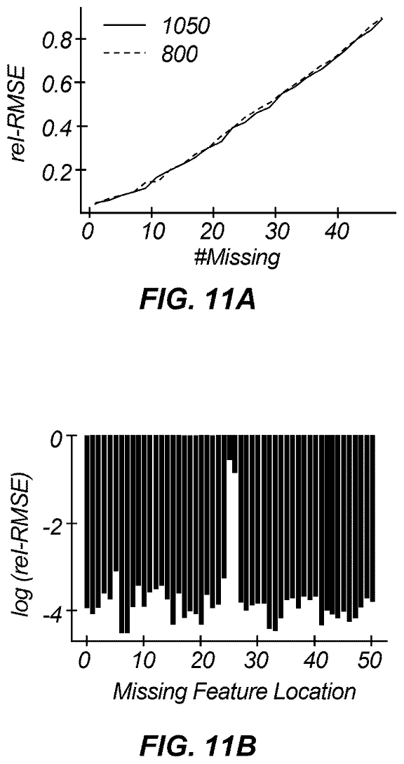

Partially-specified system completion was illustrated for two different data sizes (training+validation) with 800 and 1050 instances. FIG. 11A shows the mean of the relative root mean squared error (RMSE) over the scaled predicted and true values of the missing feature across the three repeats and the five validation folds. The relative RMSE was calculated with respect to a baseline predictor that uses the average value of the missing features as their estimate. The relative RMSE was computed whenever the partially specified system was successfully completed (i.e., when the completed system has a high pdf value, see Example 3). As expected, the prediction becomes worse when the number of missing features increases or the number of data instances decreases. A larger number of features with missing values implies one has less information about the system, hence the predictions are worse than when fewer features have missing values. With a larger number of missing features, prediction using the disclosed techniques approaches that of the baseline predictor.

The efficacy of partially specified system completion depends on what feature is missing. In FIG. 11B, the mean of the relative RMSE (log values to the base 10) across the five validation folds for estimating the value of a feature from the rest of the features can be seen. The x axis shows the location of the missing feature. For example, missing feature at location 5 means that all features except the 5th feature were used to estimate its value. Features 0-24 are system inputs and features 25 onward correspond to the system response. It was observed that features 25 and 26 (that correspond to the two system objectives) have the highest value of the relative RMSE.

Next, the use of disclosed techniques for partially specified system optimization are illustrated. A solution from the NDF of the past simulation logs is selected. The selected solution has objective values of [0.1741,0.1271] and satisfies all the constraints. The aim is to generate solutions that have an improved value of the first objective and are at least as good as the selected solution in the second objective value. The desired system response is a vector of size 26 (two objectives and 24 constraints). Multiple desired system responses are generated using the methodology presented in FIG. 7A.

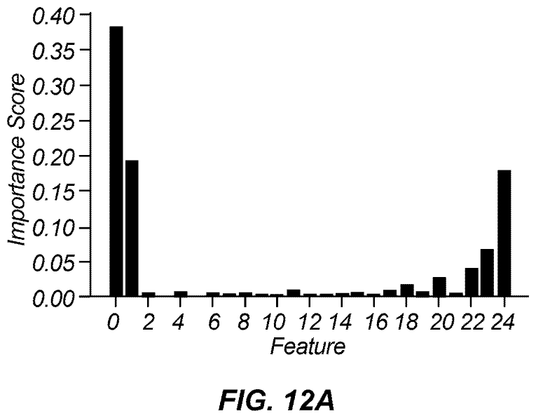

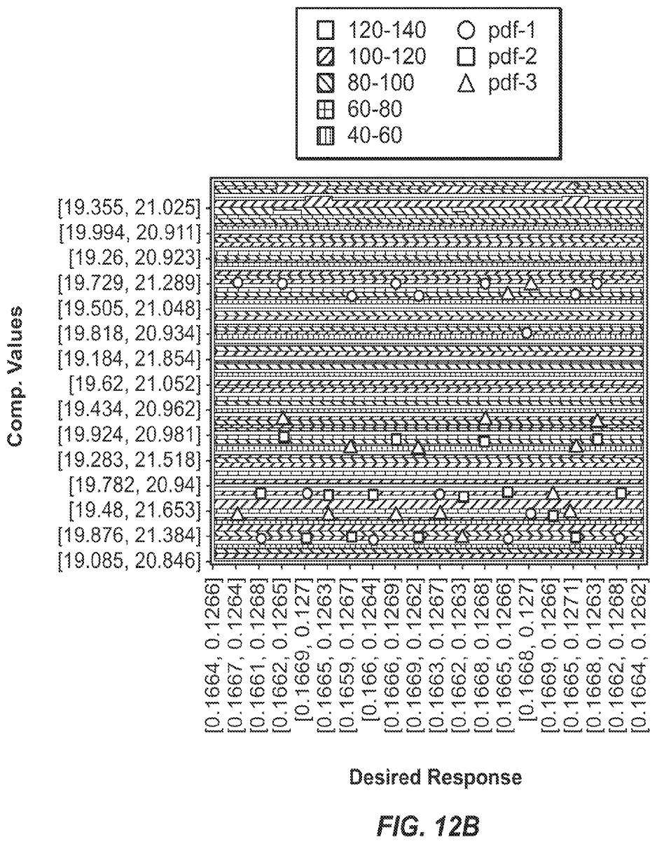

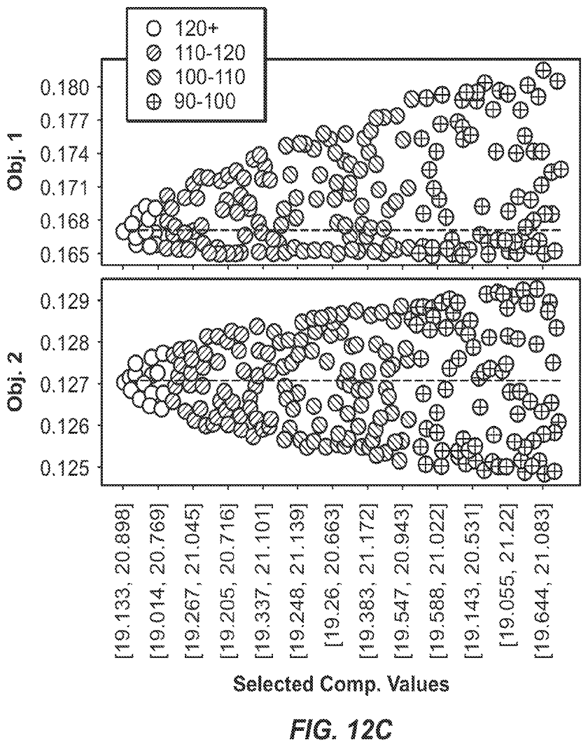

During active learning, the reference to the solution with the best value of the first objective is dynamically updated while ensuring it is least as good as the selected solution in the second objective value (i.e., 0.1271). The samples are generated around the reference solution to ensure that they meet all the 24 constraints. A gradient boosted regressor (XGBRegressor) is used on the logged data to determine the importance of each feature in determining the first objective value. The importance score measures the contribution of each feature to predicting the target output. The feature importance is calculated using the frequency (higher frequency implies more importance) at which a particular feature is used to split the data in the decision tree used in the XGBRegressor model. FIG. 12A shows the importance score of each feature. Partially specified system optimization was performed for different choices (5, 10, and 20) of the number of variable inputs. The indices of the variable inputs were selected based on the importance score. E.g., when there were five variable inputs, the five most important features obtained using the importance score were selected. As will be understood, the choice of the variable inputs can also be based on other criteria, such as domain expertise or parts availability.

The three versions of partially specified system optimization mentioned in Example 4 were used. The results were compared with a baseline version that generates candidate solutions using only the expected value of the missing features given the present features, i.e., f( [symbol] ) from Eq. (2). Partially specified system optimization were described, using Version 1 from Example 4. First, all the simulations from the past logs that do not meet the constraints on system response were removed. The information from these simulation logs (B) was incorporated by training the surrogate model with min(5000, cardinality (B)) past system responses. N_init=100 LHS samples within 10% of the input corresponding to the selected solution with objective values [0.1741,0.1271] were generated and simulated. Generating candidate solutions in the neighborhood of the selected solution helps one explore the region near the solution that one aims to improve. The past system responses were used to obtain the number of GMM components from a search space (mix_space) with a range of [1,200) components. Alg. 2 was used to generate num_des_resp_sol candidate solutions. num_des_resp_sol was randomly selected from the [10,50] range in each iteration. Alg. 1 was used to generate N_inv=1000*num_des_resp_sol desired system responses to improve the value of the objective function. The GMM was trained on the top num_train samples. num_train was randomly selected between lb_train=5000 and ub_train=10000 samples. If there were fewer than num_train samples in the buffer, all the samples were selected. The search for the number of GMM components was stopped when the number of simulations performed during partially specified system optimization exceeds gmm_frz_sim=10000 simulations. Once the number of simulations exceeds gmm_frz_sim, the GMM was only updated with the new simulation data. The aim is to improve the objective values by pr %. pr was set to pr=pr_init=pr1 to a value in the (0.1,5)% range. If a performance improvement for was not observed for sam_th1=5 iterations, pr was set to pr=pr2 to a value in the (0.1,1)% range. The best solution (best_config, best_obj_ctr) was updated upon observing an improvement in system performance. The top num_des_resp_sol candidate solutions were returned based on the corresponding pdf values from a total of N_inv candidate solutions generated using Alg. 2.

Next, Alg. 3 was used to generate total_can_to_return=10*num_des_resp_sol more candidate solutions (i.e., 10× the candidate solutions generated using Alg. 2) by sweeping over the search space of the variable inputs. The solutions generated in Alg. 2 were passed along with their pdf values. If the pdf value corresponding to the solution from Alg. 2 was above pdf_thresh=0.0001, nbr_of_req_per_ind samples within pr_inp_pr % of the values of the variable inputs in the candidate solution were generated. nbr_of_req_per_ind were randomly selected from number of samples in the [1000,2000] range and pr_inp_pr % randomly from the [0.1,5]% range at each iteration. Random selection helps explore candidate solutions at varying precision, thus potentially avoiding performance saturation. If the pdf value corresponding to the candidate solution is below pdf_thresh, one can generate 2*nbr_of_req_per_ind samples within the range of the indices corresponding to the variable inputs (var_inp_idx). Finally, total_can_to_return candidate solutions were returned with the highest pdf values.

If an improvement in system performance for sam_th1=10 iterations was not observed during partially specified system optimization, candidate solutions within config_sam_pr2=1% of the values of the variable inputs (var_inp_idx) corresponding to the best solution (best_config) were generated. The optimization was repeated until meeting the termination criteria. If an improvement in performance was not observed for a predetermined number of iterations (here, 25 iterations) or if the optimization runs for a predetermined period of time (here, about 22 hours) (allowing the last set of candidate solutions to generate and simulate) on the processing unit(s) (here, an AMD 7H12 Processor with 32 CPU cores), the optimization was terminated. Version 2 is similar to Version 1 with only one change. Partially specified system optimization is started only with Alg. 2 and switch to Version 1 (i.e., use both Alg. 2 and Alg. 3) upon not observing performance improvement for a predetermined number of interactions (here, 15 iterations). In Version 3, the following scheme was used to generate the candidate solutions:
(1) Use Alg. 2 to generate num_des_resp_sol=N_inv candidate solutions randomly in the [10,50] range.
(2) Generate candidate solutions using Version 1 upon observing a saturation in performance for 15 iterations.
(3) Use Step (1) to generate candidate solutions upon observing an improvement in system performance.
(4) Repeat the above steps.

Hence, Version 3 uses a dynamic switching mechanism. The three versions are compared with a baseline version that only uses Step 1 from Version 3 (above) to generate candidate solutions. The baseline version is a modified method of the GMM-based candidate solution generation method used in INFORM (see Terway, P., et al., “INFORM: Inverse design methodology for constrained multi-objective optimization”, IEEE Trans. on Computer-Aided Design of Integrated Circuits and Systems (2022)). It was modified to generate candidate solutions corresponding to only the variable system inputs. The candidate solutions use the expected value of the variable inputs given the present features. The present features are the values of the fixed system inputs and the desired system response. (Note, unless specified otherwise, the same setup was used for the other real-world examples disclosed below).

The decision the disclosed technique makes when generating candidate solutions can be explained. Results are presented when performing partially-specified system optimization with two variable inputs. The two most important features (using the importance score) are selected as the variable system inputs. For ease of plotting, only the results with two variable inputs are shown, but the analysis may hold for any number of variable inputs. FIG. 12B shows an example of the log (base 10) values in various categories (40-60, 60-80, 80-100, 100-120, and 120-140) of the pdf computed for different combinations of the desired system response on the x axis and the component values on the y axis. 20 Sobol samples were generated as the desired system response to improve the performance of a system with objective values of [0.1670,0.1271]. These objective values represent the best (in the first objective) system response from the simulation buffer during partially specified system optimization with two variable inputs. The aim is to improve system performance and explain the choice of candidate solutions. The other 24 desired responses are set to meet the constraints. 1500 Sobol samples were generated around the values of the variable inputs corresponding to the chosen objective values. For each choice of the variable inputs and desired response combination, the pdf value was determined. That several promising candidate solutions exist for a given response can be inferred from the figure. The pdf value is a proxy for the confidence in the candidate solution achieving the desired response. One can also plot the top three pdf values for each desired response. The highest pdf value is labeled pdf-1, the second highest pdf-2, and the third highest pdf-3. Thus, the disclosed technique presents a way to generate multiple candidate solutions and their confidence values to explain the decision to the system designer.

Next, some of the candidate solutions obtained when the desired objective values of the response were set to [0.1667,0.1264] can be simulated. The other 24 system response values were set to meet the constraints. FIG. 12C shows the best value of the objective function (from the simulation logs) using black dotted lines. The top 250 candidate solutions (out of 1500) based on the pdf values of the completed system were selected and simulated. The objective values and the pdf values of the candidate solutions that meet the constraints are shown in FIG. 12C. The pdf values show the associated confidence before actually evaluating the system with chosen candidate solutions. It is observed that the solutions corresponding to high (low) pdf values have a lower (higher) variation in the response. A high pdf value is akin to exploitation, while a low pdf value leads to exploration.

Next, we present partially-specified system optimization results with different numbers of variable inputs: 5, 10, and 20. Hypervolume is a measure of the solution quality in MOO problems, derived by measuring the size of the dominated portion of the objective space bound by a reference point. One can use the setup described in the PyMOO documentation to compute the hypervolume. One can normalize the hypervolume to the maximum hypervolume across the different optimization schemes and the different number of choices for the variable inputs. Ver-01, Ver-02, Ver-03 refer to the three versions for partially-specified system optimization as disclosed herein. The results are compared with that of the baseline version (labeled Exp.) that generates candidate solutions using only the expected value of the missing feature, similar to the GMM-based inverse design used in INFORM. When the number of variable inputs is low, the four optimization methods lead to comparable solutions and a similar hypervolume. With a larger number of variable inputs, Ver-01 leads to a higher hypervolume at the cost of more simulations. As Ver-01 searches along two dimensions (Alg. 2 and Alg. 3) throughout the optimization, Ver-01 is expected to be less sample-efficient. In general, the baseline version has the worst solution quality. The baseline version does not account for confidence in candidate solution quality nor does it explore the dimension of the variable inputs. Exploration along the dimension of the variable inputs enables the handling of multimodal system behavior. The optimization time in hours (method) with 5 variable inputs are: 6.08 (Ver-01), 6.15 (Ver-02), 8.57 (Ver-03), and 2.79 (Exp.). The numbers with 10 variable inputs are: 15.45 (Ver-01), 22.01 (Ver-02), 22.09 (Ver-03), and 22.01 (Exp.). With 20 variable inputs, the time taken are: 22.12 (Ver-01), 22.22 (Ver-02), 22.02 (Ver-03), and 22.15 (Exp.). As the number of variable inputs increases, the search space increases, which in turn leads to an increase in the optimization time. Note that sometimes even the baseline version (Exp.) consumes similar or more time than Ver-01. This happens because the time needed to learn the optimum GMM exceeds the simulation time for the candidate solutions. However, in general, Ver-01 needs more #simulations than the baseline version as it generates candidate solutions using both Alg. 2 and Alg. 3.

### Example 7 (Synchronous Optimal Pulse-Width Modulation of Seven-Level Inverters)

This problem is similar to that in Example 6. There are two objectives (minimization of both), 24 constraints (all ≤0) on the system response, and 25 decision variables. The same experimental setup used in the earlier problem can be utilized. Two variable inputs were selected and aim to improve the solution with objective values [1.2870, 0.0147].

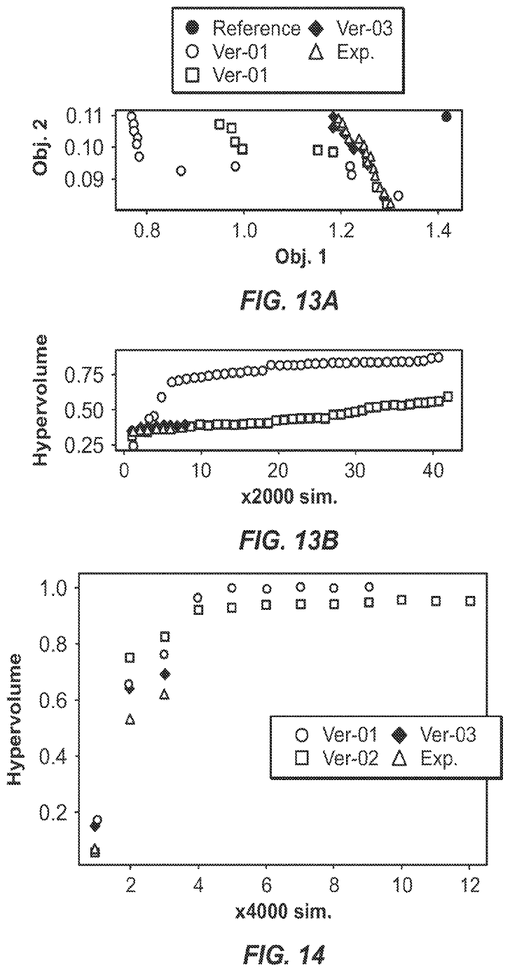

Partially-specified system optimization with 5 variable inputs are shown in FIGS. 13A and 13B. Optimization was also performed for 10 and 20 variable inputs. The hypervolume obtained using Ver-01 is more than 50% better than that obtained using the baseline version. The optimization time in hours (method) with 5 variable inputs are: 18.45 (Ver-01), 22.10 (Ver-02), 16.83 (Ver-03), and 20.32 (Exp.). The numbers with 10 variable inputs are: 14.82 (Ver-01), 22.22 (Ver-02), 22.15 (Ver-03), and 22.03 (Exp.). With 20 variable inputs, the time taken are: 22.14 (Ver-01), 22.18 (Ver-02), 22.07 (Ver-03), and 22.23 (Exp.).

### Example 8 (Multi-Product Batch Plant)

This problem has three objectives (minimization of all), 10 constraints (all ≤0), and 10 decision variables. A solution is selected with objective values [173275.261, 17757.243, 1583.530] from the simulation logs. Samples within 10% in the neighborhood of the inputs corresponding to the selected solution were generated and simulated.

Relative RMSE across the three repeats and the five validation folds with dataset of sizes 1000, 5000, and 7000 were determined. The mean of the relative RMSE (log value) across the five validation folds was determined when estimating the value of a single feature from all other features. It was observed that for some of the features, the prediction using the disclosed technique is close to that obtained using the baseline predictor (log value close to 0). A partially specified system completion can be illustrated through an example. Consider the following query by the designer:
Inputs: [2.80, ?, 1.21, 1740.99, 2411.09, ?, 7.68, ?, 365.71, ?]
Response: [172450.29, 18681.33, ?, ?, ?, −89.83, −256.33, −15.04, ?, ?, −9.34, −21.34, −4.45].

The designer is interested in determining the value of the missing features (inputs and the response), indicated by a ‘?’ using the present features from the partially-specified system, specified in the query. The disclosed methods predict the following completed system:
Inputs: [2.80, (3.04) 3.04, 1.21, 1740.99, 2411.09, (2331.53) 2331.24, 7.68, (8.45) 8.45, 365.71, (204.06) 204.02]
Response: [172450.29, 18681.33, (1667.47) 1668.0, (−4332.53) −4332.0, (−193.39) −193.48, −89.83, −256.33, −15.04, (−3.04) −3.04, (0.32) 0.32, −9.34, −21.34, −4.45].

The predicted values are shown in parentheses. The value outside the parenthesis depicts the ground truth value. It is observed that the predicted and the true values are very close to each other. The log value of the pdf of the completed system is 32.41, indicating a high confidence in the prediction. If the pdf value of the completed system is low or the designer requires multiple candidate solutions, one can sweep over multiple possible values for the features corresponding to the missing indices. Then, one can select a few values of the missing features based on the pdf value of the completed system.

After determining each feature's importance score for obtaining the first objective value, the pdf value of the candidate solutions for each desired response for five variable system inputs was determined. Five variable inputs were selected to improve a solution with objective values [172815.8, 17757.2, 1583.5]. FIG. 14 shows the hypervolumes with nine inputs. The optimization time in hours (method) are: 7.06 (Ver-01), 10.79 (Ver-02), 3.94 (Ver-03), and 4.58 (Exp.).

### Example 9 (Unmanned Underwater Vehicle)

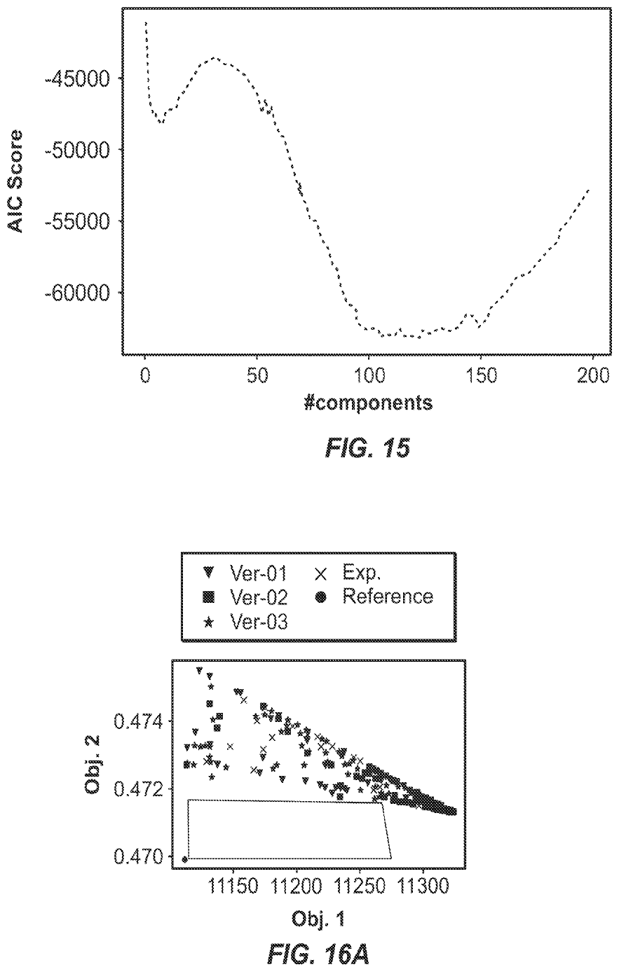

The disclosed method can be evaluated on an unmanned underwater vehicle (UUV) application for ocean surveillance. The problem has three objectives (maximization of the first two and minimization of the third), four constraints, and 12 decision variables. The four constraints are: c1>0.1, c2>0, c3∈[5.5, 7.5], and c4<11, 030. For this problem, suppose one has a solution with the following objective values: [11111.1, 0.57, 318.5], but do not have access to past simulation logs. Hence, one learns the system response in the neighborhood of the input corresponding to the selected solution. One can generate and simulate input data within 10% of the input values corresponding to the selected solution. One can generate the mean of the relative RMSE across three repeats and the five validation folds with datasets of sizes 1000, 4000, and 6000, as well as the mean of the relative RMSE (log value) across the five validation folds when estimating the value of a feature using the rest of the features. Note that when using a datasize of 1000, two minima were observed when plotting the AIC score versus #components, as shown in FIG. 15. The AIC score is plotted based on data in the first training fold. The minima are located at 8 and 123 components. Although the AIC score is lower at 123 components, the #components was chosen as 8 for the first training fold. The search space was limited for the #components in the GMM for the remaining training folds in the [1,40) range to ensure that the least AIC score corresponding to the first minima was picked. With a data size of 1000 and feature dimension of 19, a large number of components (123) indicates overfitting on the training data. Still, with 123 components used to complete a partially specified system, the designer will observe that the disclosed technique invokes sweep (see FIG. 5) on several occasions even with a single missing feature: an indication of overfitting on the train data.

The importance score of each feature in determining the first objective was graphed. Log pdf values of several candidate solutions (with two variable inputs) were plotted for each desired response. Graphs similar to those in FIG. 12C were created to show the three objective values and log pdf values of the top 250 candidate solutions that meet the constraints when the desired objective values were set to [11120.827, 0.4705, 317.946].

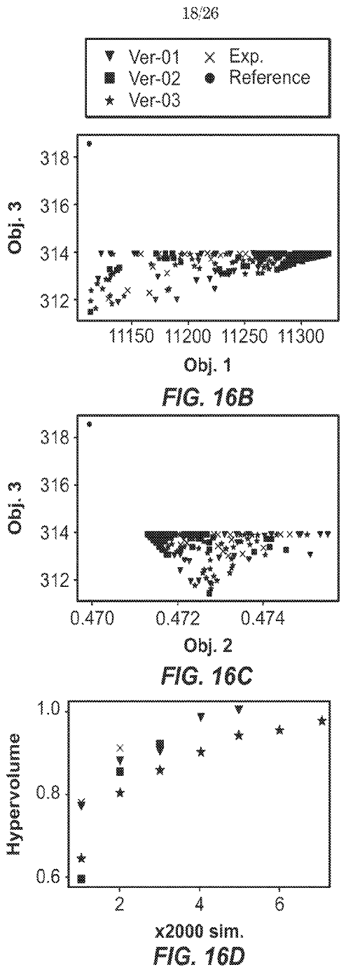

Partially-specified system optimization and hypervolume with five variable inputs is illustrated in FIGS. 16A-16D. In this example, N_init was increased to 1000 since there was no access to the past simulation logs. The optimization time in hours (method) are: 2.03 (Ver-01), 0.94 (Ver-02), 3.04 (Ver-03), and 0.43 (Exp.).

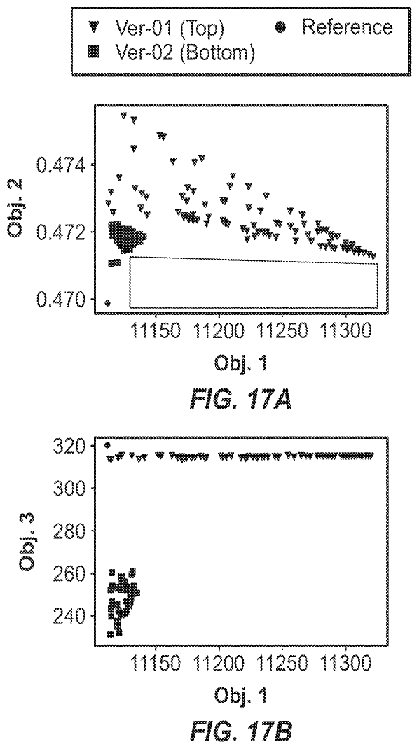

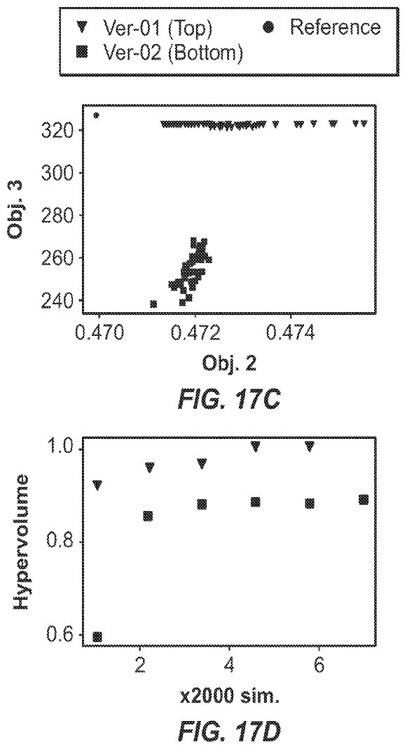

FIGS. 17A-17D illustrate the comparison of partially specified system optimization when the search over the inputs is limited to the top and bottom five important features determined using XGBRegressor for the first objective. As expected, the values of the first objective at the end of the optimization are lower when we select the bottom five important features instead of the top five features.

### Error Location and Correction.

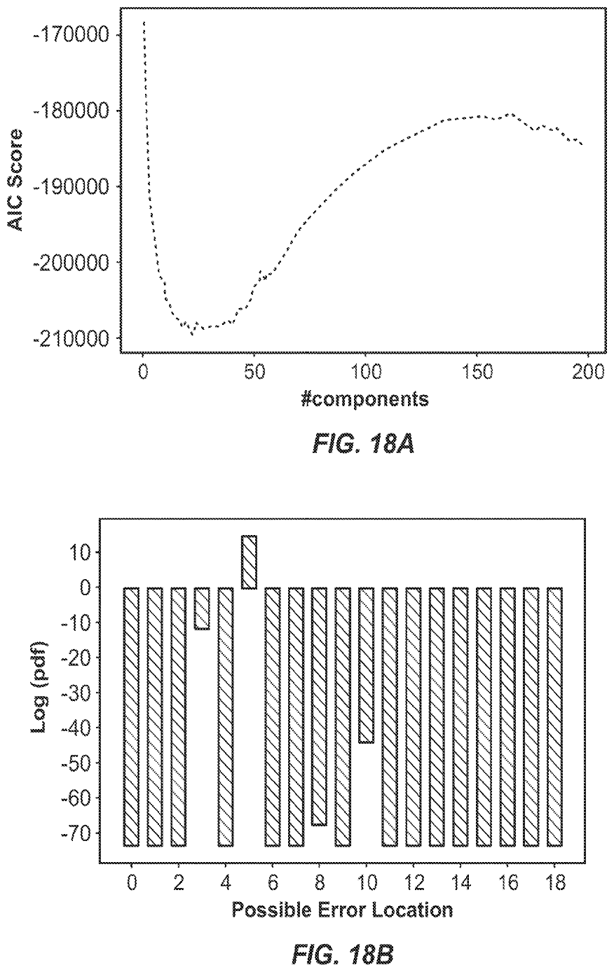

Finally, in this example, the disclosed approach is used to correct errors in the data. Data from past simulation logs where the features correspond to the system inputs and the corresponding response (objectives/constraints) was used. As earlier, #components was selected that produces the least AIC score on the training data and perform error analysis on the validation data. FIG. 18A plots AIC score versus #components for the UUV training data. A GMM with 22 components (minimum AIC score) was used as the surrogate model. Error(s) are injected in the data from the validation fold, and corrected using the methodology discussed in Example 5. Given a new data instance, error(s) are detected, located, and corrected.

Consider the UUV example with the following inputs and response:
Inputs: [0.92, 4.59, 213.55, 1.43, 358.59, 0.569, 21.02, 0.0080, 0.107, 0.548, 1025.90, 1.43]
Response: [7942.44, 0.49, 263.30, 0.66, 395.86, 5.02, 213.55].

The log pdf value of the above observation is −48.25. Such a low pdf value indicates an anomalous behavior, as the observation does not lie within the distribution learned by the surrogate model. One can sweep over all the features one at a time and estimate the value of the swept feature using the rest of the features. One can also determine the pdf value of the data instance completed using the estimated value of the swept feature. FIG. 18B shows the log pdf value of the completed data instance at the estimated value of the swept feature. If the pdf value is low, a small number can be added so that the log value is clipped to a low value. The highest pdf value occurs for the erroneous feature (fifth feature in this case). Hence, one can replace the value of the fifth feature with its estimated value using the rest of the features.

The predicted value (log pdf) of the fifth feature is 0.553 (15.04). A high pdf value indicates that confidence in the error correction. The true value (log pdf) of the feature is 0.554 (14.65), which is close to the estimated value. The estimation error is only 0.2%.

In the above example, the pdf at the swept feature's value estimated using f( [symbol] ) was computed. In case none of the pdf values in FIG. 18B is high, despite a low value of p(x) at the measured features, one would need to modify the computation. Rather than using f( [symbol] ) to estimate the value of the missing/swept feature, one would need to sweep over possible values of each swept feature individually. For each feature, one could store the highest pdf value and the corresponding value of the swept feature. Then, one could obtain a plot similar to FIG. 18B and obtain the error location. The estimated value of the erroneous feature is the one that leads to the highest pdf value. If the designer requires multiple possible values of the erroneous feature, one can sweep over a range of values for this feature. One can then select a few possible values (from the multiple values of the swept feature) based on the pdf value of the system completed using the swept feature's value.

The above method can be extended to detect up to two errors in the measured features. Consider the following data instance for the UUV example:
Inputs: [0.9703, 4.51, 206.68, 1.38, 342.83, 0.599, 21.15, 0.0079, 0.104, 0.496, 1026.66, 1.44]
Response: [7695.97, 0.7543, 278.23, 0.69, 407.89, 5.08, 206.68].

The pdf value of the above observation is 0, indicating an anomaly. As earlier, one can sweep over each feature and plot the log pdf value of the completed system. It is observed that none of the pdf values are high. This can happen due to two reasons:
(1) f( [symbol] ) is not a good estimate of the value of the missing/swept feature. In such a case, one needs to sweep over the multiple possible values of each swept feature.
(2) There are two possible errors in the measurements.

The second case is explored. One can sweep over all combinations of two features out of the 19 features (171 combinations). One can estimate the value and the pdf of the feature in each combination using all other features. When looking at the log pdf value at each combination, the highest pdf value occurs at combination [0,13]. It is determined that features 0 and 13 are potentially erroneous and estimate their values using the rest of the features. The predicted values (log pdf) of these two features are [0.8870, 0.4850](15.81). A high pdf value indicates that we are confident in the predictions. The true values (log pdf) of the features are [0.8868, 0.4851](15.76). They can be seen to be close to the estimated value.

### Example 10 (Error Analysis)

An error analysis of Examples 6-9 can be performed. As earlier, a 5-fold cross-validation on the logged data can be performed for each example. The GMM (#components and the GMM parameters) can be obtained from 80% of the data and evaluate it on the remaining 20% of the data. For each data instance in the validation fold, locations are randomly selected to inject error. The number of locations where errors are injected is varied from 1 to 3. At each selected location, the true observation (scaled value) is multiplied with a randomly generated number either in the [0.01,0.5] or [1.5,3.0] range. It is randomly determined whether each observation was scaled up or down. Injecting errors in both directions mimics real-world systems where the direction of the errors is not known a priori. As earlier, the process was repeated thrice for each data in the validation fold. When a single error was injected, the only search was for all possible combinations of a single error. Similarly, all possible combinations of two errors was searched when injecting two errors. If #errors is not known beforehand, but capped at a maximum value (e.g., a maximum of three errors), the process would have to sweep all possible combinations of single, two, and three errors at a time to perform error analysis, as shown earlier in the UUV example. If the pdf of the corrected data is above a threshold probability (pdf_thresh_err) of 0.01, the feature values are replaced with that suggested by the disclosed method. Otherwise, the suggestions are discarded, as the method fails to correct the error.

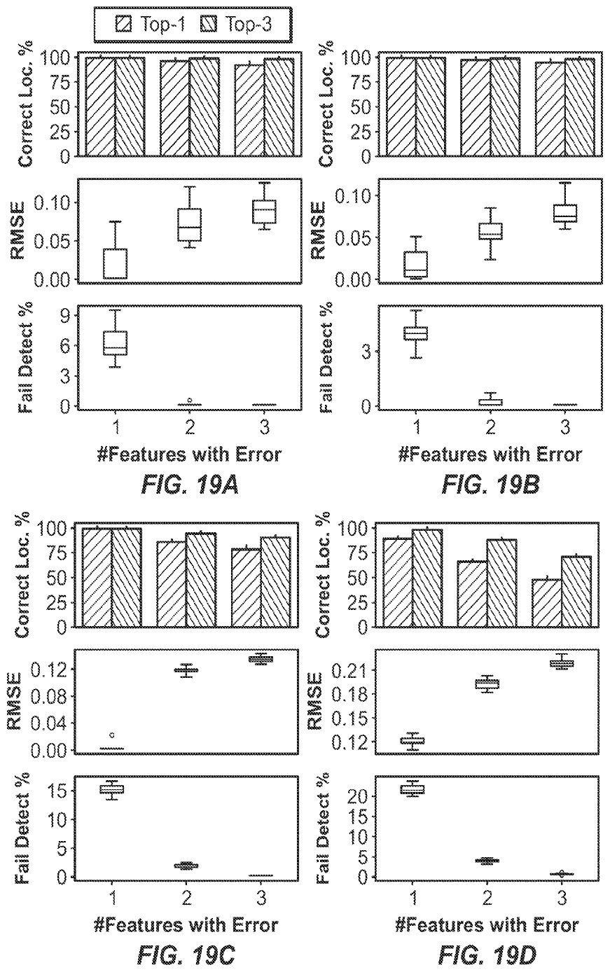

FIGS. 19A-19D show the percentage of times the correct error location was identified on the data where the method detects an anomaly (top row), RMSE between the true and predicted values of the features with error (middle row), and the percentage of data where the disclosed technique fails to detect an anomaly (bottom row). The analysis (top two rows) was performed only on the data where the disclosed technique detects an anomaly.

The disclosed technique may fail to detect anomaly for two reasons: (1) the given observation (data after error injection) lies within the learned distribution (i.e., pdf>pdf_thresh_err) or (2) the system after correcting the erroneous feature values has a low pdf value (i.e., pdf<pdf_thresh_err). The Top-1 legend in the top row indicates the percentage (on the data instances where an error was detected) when the most confident (highest pdf value) predictions of the error locations match the true error locations. Similarly, the Top-3 legend indicates the percentage when the true error location is within the top three confident predictions of the error locations. When a single feature has an error, the system fails to detect the error in about 6% of the validation data (that have errors) for the three-level inverter example. As the number of erroneous features increases, the possible search space for the locations of errors increases. For example, in the power electronics examples with 51 features (inputs+response), the search space for three possible error locations has 20825 (51 choose three) choices. However, there is also larger information from 48 correct features to predict the values of the incorrect features. The system predicts Top-1 error locations (when values of three randomly selected features are erroneous) with a mean accuracy of about 95% (on the data where it detected error) for the seven-level inverter example. The UUV example with 19 features has a lower error detection rate than other examples. With fewer features, although the search space for possible error locations is smaller, it also inherits a smaller context from the other features to infer the true error locations. As expected, it is observed that the RMSE between the true and the estimated values of the erroneous features increases as the number of features with error increases. It is also observed that the number of discarded observations decreases when the number of erroneous features increases. When only one feature has an error, it is possible that the observations (after error injection) may still lie within the distribution of the surrogate model. However, the chances of an observation lying within the learned distribution reduce as the number of erroneous features increases.

The disclosed technique addresses several challenges encountered in real-world system design: system completion, partially-specified system optimization, and error correction. Without the need for additional redundant components, the disclosed technique detects possible error(s), identifies the location of the error(s), and finally presents a remedial action. The disclosed technique also provides an explanation of the decisions it makes during system design.

The disclosed technique demonstrates the importance of modeling the data distribution to tackle several real-world system design challenges. Many AI models use a point estimate to derive a surrogate model. However, a lack of awareness of the data distribution often causes the models to perform poorly on unseen data. In contrast, the disclosed technique first determines whether the unseen data are within the distribution of the training data. In case the data are out of distribution, rather than making a poor prediction, the disclosed technique raises a flag informing the designer that it cannot make a prediction. The flag can be used by the designer to perform inference through other means (e.g., performing actual simulation). Using the same surrogate model, the disclosed technique can predict values of the missing inputs and/or response. It also assigns a confidence value to the predictions. The disclosed technique is agnostic to the amount of uncertainty in the system response, thus allowing it to model multimodal (several system inputs producing the same response) system behavior.

The disclosed technique can enable symbiotic human-AI co-design of systems. Often, the designer has access to only a part of the system inputs and may have some desired performance values in mind. The disclosed systems and techniques aid the designer in predicting missing feature values, thus avoiding the need to invoke a costly simulator run for evaluation. The method differs from many other AI-based design methods that use a surrogate model to map system inputs to the response. The disclosed technique is agnostic to the number and locations of the missing feature values. The surrogate model performs better if the designer provides more prior information. The disclosed technique presents an explainable AI framework by assigning a confidence value to the candidate solution(s). Thus, the designer can decide, based on the confidence value, whether to prefer exploration or exploitation. Moreover, the framework discovers several candidate solutions for a given desired system response. Most optimization tools are agnostic to the choice of inputs, as long as system performance is the same. However, providing an array of choices to the designer may be helpful in a setting where one set of input values is preferable over others. If two sets of input values exhibit similar performance, the designer can use the input values that cost less. The disclosed technique also identifies and corrects errors in the data. The error correction mechanism can be used to enhance the safety of real-world systems.

When generating multiple candidate solutions for a desired system response, the disclosed technique requires sweeping over multiple possible values of the variable system inputs. The values taken by the candidate solutions are only as good as the precision of the values of the swept variables. One can randomly select a different number of possible candidate solutions generated during each iteration of partially specified system optimization. Selecting a different number of candidate solutions helps to explore candidate solutions with varying precision. Perhaps, another strategy to generate possible values for candidate solutions may help overcome the limitation imposed by sweep precision. The disclosed technique may not be the fastest framework to arrive at a solution if the designer cares only about the end result of the optimization.

Evolutionary algorithms are likely to be faster, provided that system simulation is time-efficient. The complexity of training a GMM is O(NKD³), where N denotes #data points, K #components, and D the dimension or #features. One option to scale the disclosed technique across larger #features is to reduce the complexity to O(NKD²). Rather than using all the data during transfer learning, the disclosed technique can select only the good data, based on the pdf value, when transferring knowledge from one use case to another.

### Example 11 (Example Use Case for a Synchronous Optimal Pulse-Width Modulation of Three-Level Inverter)

### Completing a Partially Specified System

Consider the example of a synchronous optimal pulse-width modulation of three-level inverter. This system has 25 inputs, and 26 outputs (2 objectives and 24 constraints). FIG. 11A illustrates the efficacy of the disclosed systems and techniques when completing a partially specified system. Here, one can randomly mask some of the features in the test instance and use the remaining information to predict the masked values, thus completing a partially specified system. In comparison to a baseline estimator that predicts the masked values by using the mean values of the missing features, The exemplary system's performance is up to an order of magnitude better.

### Uncertainty Modeling and Explainable Decision

Consider a synchronous optimal pulse-width modulation of three-level inverter with the following values of the two objectives: (0.1670, 0.1271). The goal is to improve the value of the first objective (minimize), without compromising on the value of the second objective while meeting all the constraints on the output. The exemplary system uses the past simulation data to propose candidate solutions and assigns confidence to those solutions. FIG. 12B shows the confidence of candidate solutions assigned for each desired response to improve the performance of the system (solutions with higher pdf values correspond to solutions with higher confidence). As illustrated in FIG. 12C, solutions with higher confidence have a lower variation in response in comparison to solutions with lower confidence. Depending on the use case, a designer may choose a higher confidence solution if one wishes to have a certainty in improvement in performance or a lower confidence solution to explore the design space for possibly a larger improvement in performance.

### (1) Improving the Performance of a Legacy System

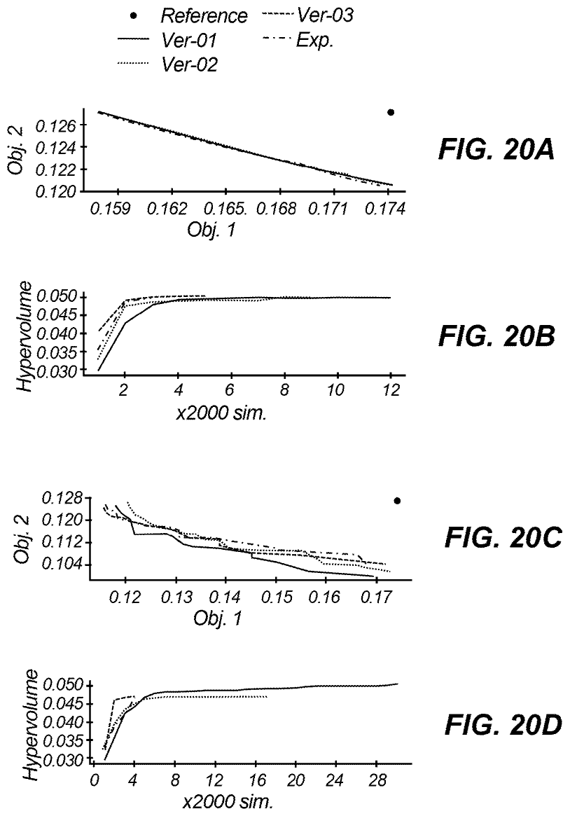

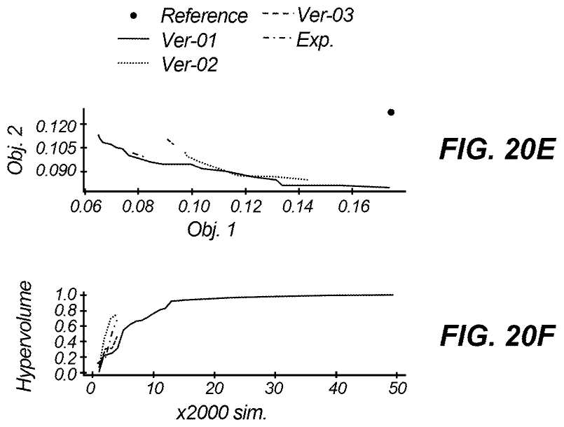

As an example, one can select a legacy solution with the following objective values: [0.1741, 0.1271]. Once again, the aim is to improve the performance of the first objective value without compromising on the performance of the second objective. One can use active learning (see FIG. 9) to continually improve the system performance. We change the number of variable inputs to 5, 10, and 20. FIGS. 20A-20B (5 inputs), 20C-20D (10 inputs), and 20E-20F (20 inputs) show that the improvement in performance is greater with more number of variable inputs. This is illustrated with a higher hypervolume and more solutions with a lower value (hence better) of the objectives. With 20 variable inputs, the hypervolume is higher by about 20% in comparison to the next best optimization method. The best value of the first objective is about 0.065 in comparison to 0.08 obtained by the next best optimization method.

### Error Detection, Location, and Correction

FIG. 19A illustrates the efficacy of the disclosed systems and techniques in correcting errors. As the number of errors increases, the error detection accuracy improves from about 6% failure rate to close to 0% when the number of errors increases from one to three. The RMSE between the estimated values of the features with error and the true feature values degrades with a larger number of errors, as we have lesser information to predict the true feature values. The top 1 error detection accuracy degrades slightly from about 95% to about 90% when the number of features with error increases.

Various modifications may be made to the systems, methods, apparatus, mechanisms, techniques and portions thereof described herein with respect to the various figures, such modifications being contemplated as being within the scope of the invention. For example, while a specific order of steps or arrangement of functional elements is presented in the various embodiments described herein, various other orders/arrangements of steps or functional elements may be utilized within the context of the various embodiments. Further, while modifications to embodiments may be discussed individually, various embodiments may use multiple modifications contemporaneously or in sequence, compound modifications and the like.

Although various embodiments which incorporate the teachings of the present invention have been shown and described in detail herein, those skilled in the art can readily devise many other varied embodiments that still incorporate these teachings. Thus, while the foregoing is directed to various embodiments of the present invention, other and further embodiments of the invention may be devised without departing from the basic scope thereof. As such, the appropriate scope of the invention is to be determined according to the claims.

1. A method for partial system completion and/or optimization, comprising:
learning a surrogate model from previous simulation logs of a system, where system inputs and responses are concatenated into a single vector, and a joint distribution is learned; and
using the surrogate model to predict any set of missing inputs from a partially specified system and/or predict a response from a partially specified system.

2. The method of claim 1, wherein a Gaussian Mixture Model is used to learn the surrogate model.

3. The method of claim 1, further comprising determining a probability density function of a completed system.

4. The method of claim 3, wherein the probability density function is used as a measure of a confidence in any predicted missing inputs or predicted response, where a higher probability density function value indicates greater confidence.

5. The method of claim 4, further comprising searching over a space of variable components.

6. The method of claim 5, wherein searching over the space of variable components includes using inverse design to generate a set of desired system responses to improve system performance.

7. The method of claim 6, wherein the surrogate model is used to predict one or more possible system completions for each system response of the set of desired system responses.

8. The method of claim 7, wherein each predicted possible system completion acts as a candidate solution, the method further comprising simulating the system with each candidate solution and using a response from simulating the system to update the surrogate model.

9. The method of claim 5, wherein searching over the space of variable components includes generating multiple possible values of one or more variable inputs for a given system response.

10. The method of claim 9, wherein each value of the one or more variable inputs and the partially specified system is considered a completely specified system, the method further comprising using the surrogate model to determine a probability density function of each completely specified system.

11. The method of claim 5, wherein searching over the space of variable components includes both:
using inverse design to generate a set of desired system responses to improve system performance; and
generating multiple possible values of variable inputs for a given system response.

12. The method of claim 5, further comprising utilizing some of the partially specified system based on a value of the probability density function.

13. The method of claim 5, further comprising identifying a cause of anomalous behavior.

14. The method of claim 13, where in identifying the cause of anomalous behavior includes determining a probability density function of a given observation using the surrogate model, where a value below a threshold indicates the given observation is anomalous.

15. The method of claim 13, further comprising determining a remedial action to be taken.

16. The method of claim 15, wherein determining the remedial action includes:
assuming that a subset of inputs and response are missing, while a remainder set of inputs and response are specified; and
sweeping over a plurality of combinations of the subset of inputs and response that are missing, where the remainder set of inputs and response are configured to act as a partially specified system, and predicting values of the subset of inputs and response that are missing and an associated probability distribution function value from the partially specified system.

17. The method of claim 16, further comprising determining one or more predicted values of the subset of inputs and response that are missing is incorrect when the associated probability distribution function value is above a first threshold.

18. The method of claim 16, further comprising replacing erroneous measurements with a predicted value from other measurements to ensure that a corrected system behavior lies within a distribution of past observations.

19. The method of claim 16, further comprising using multiple system observations to break a tie based on a majority vote if different subsets of the plurality of combinations of the subset of inputs and response that are missing yield associated probability distribution function values above a second threshold.

20. A non-transitory computer readable storage medium containing instructions that, when executed by one or more processing units, causes the one or more processing units to, collectively, perform a method of claim 1.

21. A system, comprising one or more processing units operably coupled to a non-transitory computer readable storage medium according to claim 20.
